(19) United States
(12) Patent Application Publication
(10) Pub. No.: US 2024/0272444 A1
(43) Pub. Date: Aug. 15, 2024

(54) LASER PROCESSING SYSTEM, LASER PROCESSING METHOD, AND ELECTRONIC DEVICE MANUFACTURING METHOD

(71) Applicant: Gigaphoton Inc., Tochigi (JP)

(72) Inventors: Yasufumi KAWASUJI, Oyama-shi (JP); Osamu WAKABAYASHI, Oyama-shi (JP); Akiyoshi SUZUKI, Oyama-shi (JP)

(73) Assignee: Gigaphoton Inc., Tochigi (JP)

(21) Appl. No.: 18/636,475

(22) Filed: Apr. 16, 2024

Related U.S. Application Data
(63) Continuation of application No. PCT/JP2021/041508, filed on Nov. 11, 2021.

(51) Int. Cl. G02B 27/09; B23K 26/06; B23K 26/0622; B23K 26/067; B23K 26/324; B23K 26/70; B23K 101/36; B23K 103/00; H01L 21/48; H01L 23/00

(52) U.S. Cl. CPC G02B 27/0988; B23K 26/0622; B23K 26/0648; B23K 26/0665; B23K 26/067; B23K 26/324; B23K 26/705; G02B 27/0944; H01L 21/486; B23K 2101/36; B23K 2103/42; B23K 2103/54; H01L 24/16; H01L 2224/16227

(57) ABSTRACT

A laser processing system includes a laser apparatus configured to output a pulse laser beam, a divergence adjuster configured to adjust a first beam divergence in a first direction of the pulse laser beam and a second beam divergence in a second direction which intersects the first direction, a measuring instrument configured to measure the first and second beam divergences of the pulse laser beam having passed through the divergence adjuster, a diffractive optical element configured to branch the pulse laser beam having passed through the measuring instrument, and a processor configured to control the divergence adjuster such that the first and second beam divergences approach respective target values based on measurement results of the first and second beam divergences by the measuring instrument.

### CROSS-REFERENCE TO RELATED APPLICATIONS

The present application is a continuation application of International Application No. PCT/JP2021/041508, filed on Nov. 11, 2021, the entire contents of which are hereby incorporated by reference.

### BACKGROUND

### 1. Technical Field

The present disclosure relates to a laser processing system, a laser processing method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Excimer laser beams output from KrF and ArF excimer laser apparatuses can also be used for direct processing of a polymer material and a glass material or the like, since a pulse width is several tens ns and a wavelength is as short as about 248 nm and about 193 nm.

A chemical bond in a polymer material can be cut by an excimer laser beam having photon energy higher than bond energy. Therefore, it is known that non-heating processing of a polymer material is made possible by an excimer laser beam, and a processing shape becomes beautiful.

In addition, since glass, ceramics, and the like have a high absorptance to an excimer laser beam, it is known that even a material that is difficult to be processed by a laser beam in a visible or infrared region can be processed by an excimer laser beam.

### LIST OF DOCUMENT

Patent Document
   Patent Document 1: Japanese Translation of PCT International Application Publication No. 2018-501115

### SUMMARY

In one aspect of the present disclosure, a laser processing system includes a laser apparatus, a divergence adjuster, a measuring instrument, a diffractive optical element, and a processor. The laser apparatus is configured to output a pulse laser beam. The divergence adjuster is configured to adjust a first beam divergence in a first direction of the pulse laser beam and a second beam divergence in a second direction which intersects the first direction. The measuring instrument is configured to measure the first and second beam divergences of the pulse laser beam having passed through the divergence adjuster. The diffractive optical element is configured to branch the pulse laser beam having passed through the measuring instrument. The processor is configured to control the divergence adjuster such that the first and second beam divergences approach respective target values based on measurement results of the first and second beam divergences by the measuring instrument.

In another aspect of the present disclosure, a laser processing method includes making a pulse laser beam be output from a laser apparatus, making the pulse laser beam enter a divergence adjuster configured to adjust a first beam divergence in a first direction of the pulse laser beam and a second beam divergence in a second direction which intersects the first direction, measuring the first and second beam divergences of the pulse laser beam having passed through the divergence adjuster by a measuring instrument, controlling the divergence adjuster such that the first and second beam divergences approach respective target values based on measurement results of the first and second beam divergences by the measuring instrument, and branching the pulse laser beam having passed through the measuring instrument by a diffractive optical element so as to irradiate a workpiece.

In yet another aspect of the present disclosure, an electronic device manufacturing method includes manufacturing an interposer by laser-processing an interposer substrate with a laser processing system, coupling and electrically connecting the interposer and an integrated circuit chip to each other, and coupling and electrically connecting the interposer and a circuit board to each other. The laser processing system includes a laser apparatus configured to output a pulse laser beam, a divergence adjuster configured to adjust a first beam divergence in a first direction of the pulse laser beam and a second beam divergence in a second direction which intersects the first direction, a measuring instrument configured to measure the first and second beam divergences of the pulse laser beam having passed through the divergence adjuster, a diffractive optical element configured to branch the pulse laser beam having passed through the measuring instrument, and a processor configured to control the divergence adjuster such that the first and second beam divergences approach respective target values based on measurement results of the first and second beam divergences by the measuring instrument.

### BRIEF DESCRIPTION OF THE DRAWINGS

Some embodiments of the present disclosure will be described below by way of example only, with reference to the accompanying drawings.

FIG. 1 schematically illustrates a configuration of a laser processing system in a comparative example.

FIG. 2 illustrates a beam cross section perpendicular to an optical path axis of a pulse laser beam output from an output coupling mirror.

FIG. 3 illustrates a cross section of branched light beams of a pulse laser beam entering a workpiece in the comparative example.

FIG. 4 schematically illustrates a configuration of a laser processing system in a first embodiment.

FIG. 5 illustrates a beam cross section of a pulse laser beam measured by an image sensor included in a measuring instrument, together with light intensity distributions in the V direction and the H direction.

FIG. 6 is a flowchart illustrating a laser processing method in the first embodiment.

FIG. 7 is a flowchart illustrating details of processing of calculating control parameters.

FIG. 8 is a flowchart illustrating details of processing of feedback-controlling beam divergences and beam pointings.

FIG. 9 illustrates a cross section of branched light beams of a pulse laser beam entering a workpiece in the first embodiment.

FIG. 10 schematically illustrates a configuration of a laser processing system in a modification.

FIG. 11 schematically illustrates a configuration of a laser processing system in a second embodiment.

FIG. 12 is a plan view of a mask in the second embodiment.

FIG. 13 schematically illustrates a configuration of a laser processing system in a third embodiment.

FIG. 14 is a plan view of a mask in the third embodiment.

FIG. 15 schematically illustrates a first example of a divergence adjuster.

FIG. 16 schematically illustrates the first example of the divergence adjuster.

FIG. 17 illustrates a principle that beam divergences are adjusted in the first example.

FIG. 18 schematically illustrates a second example of a divergence adjuster.

FIG. 19 schematically illustrates the second example of a divergence adjuster.

FIG. 20 illustrates a principle that beam divergences are adjusted in the second example.

FIG. 21 schematically illustrates a third example of a divergence adjuster.

FIG. 22 schematically illustrates the third example of a divergence adjuster.

FIG. 23 schematically illustrates a fourth example of a divergence adjuster.

FIG. 24 schematically illustrates the fourth example of a divergence adjuster.

FIG. 25 schematically illustrates a fifth example of a divergence adjuster.

FIG. 26 schematically illustrates a sixth example of a divergence adjuster.

FIG. 27 schematically illustrates a first example of an improved laser apparatus.

FIG. 28 schematically illustrates a second example of an improved laser apparatus.

FIG. 29 schematically illustrates a third example of an improved laser apparatus.

FIG. 30 schematically illustrates a fourth example of an improved laser apparatus.

FIG. 31 schematically illustrates a configuration of an electronic device.

FIG. 32 is a flowchart illustrating an electronic device manufacturing method.

### DESCRIPTION OF EMBODIMENTS

### Contents

1. Laser Processing System according to Comparative Example
1.1 Configuration
   1.1.1 Configuration of Laser Apparatus 1
   1.1.2 Configuration of Laser Processing Apparatus
1.2 Operation
   1.2.1 Operation of Laser Apparatus 1
   1.2.2 Operation of Laser Processing Apparatus 5
1.3 Problem of Comparative Example

2. Laser Processing System Including Divergence Adjuster 54
2.1 Configuration
2.2 Operation
   2.2.1 Main Flow
   2.2.2 Calculation of Control Parameters
   2.2.3 Feedback Control of Beam Divergences BDV and BDH and Beam Pointings BPV and BPH
2.3 Effect
2.4 Laser Processing System with Laser Apparatus 1b Including Divergence Adjuster 20
   2.4.1 Configuration
   2.4.2 Operation
   2.4.3 Effect

3. Laser Processing System Having Mask 65 Disposed on Optical Path of Branched Light Beams by Diffractive Optical Element 63 and Transferring Image of Mask 65 to Workpiece SUB
3.1 Configuration and Operation
3.2 Effect

4. Laser Processing System Making Light Having Passed Through Mask 61 Enter Diffractive Optical Element 63
4.1 Configuration and Operation
4.2 Effect

5. Details of Divergence Adjuster
5.1 Divergence Adjuster 541 that Adjusts Beam Divergence Angle
5.1.1 Configuration and Operation
5.1.2 Effect
5.2 Divergence Adjuster 542 that Adjusts Beam Width
5.2.1 Configuration and Operation
5.2.2 Effect
5.3 Divergence Adjuster 543 that Tentatively Condenses Light and also Performs Fine Adjustment by Slit
   5.3.1 Configuration and Operation
   5.3.2 Effect
5.4 Divergence Adjuster 544 that Tentatively Condenses Light and also Performs Fine Adjustment by Lens Position
   5.4.1 Configuration and Operation
   5.4.2 Effect
5.5 Divergence Adjuster 545 Including Optical Pulse Stretcher Misaligned in H Direction
   5.5.1 Configuration and Operation
   5.5.2 Effect
5.6 Divergence Adjuster 546 Including Optical Pulse Stretcher Misaligned in V Direction

6. Improved Laser Apparatus
6.1 Laser Apparatus 1e Capable of Posture Controlling Optical Resonator
6.2 Laser Apparatus 1f Including Unstable Resonator
6.3 Laser Apparatus 1g Including Amplifier PA
6.4 Laser Apparatus 1h Including Solid-State Laser
   6.4.1 Configuration
   6.4.2 Operation

7. Others

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference numerals, and any redundant description thereof is omitted.

### 1. Laser Processing System According to Comparative Example

### 1.1 Configuration

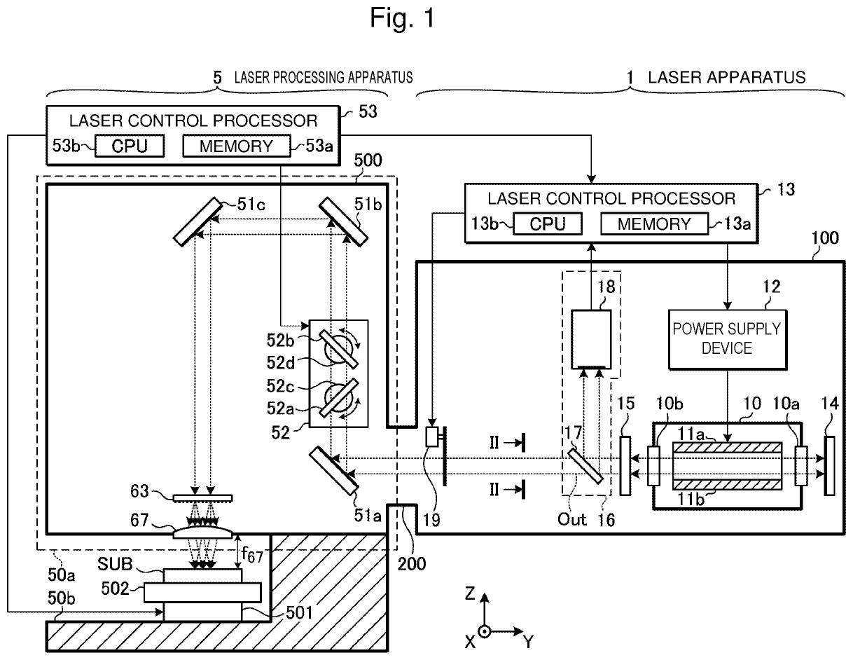

FIG. 1 schematically illustrates a configuration of a laser processing system in a comparative example. The comparative example of the present disclosure is an example recognized by the applicant as known only by the applicant, and is not a publicly known example admitted by the applicant. The laser processing system includes a laser apparatus 1 and a laser processing apparatus 5.

### 1.1.1 Configuration of Laser Apparatus 1

The laser apparatus 1 is a gas laser apparatus which outputs a pulse laser beam Out of ultraviolet light. The laser apparatus 1 includes a laser chamber 10, a power supply device 12, a rear mirror 14, an output coupling mirror 15, a monitor module 16, and a shutter 19. These components are housed in a first housing 100. The rear mirror 14 and the output coupling mirror 15 configure an optical resonator.

The laser chamber 10 is disposed on an optical path of the optical resonator. The laser chamber 10 is provided with windows 10a and 10b. The laser chamber 10 includes a pair of discharge electrodes 11a and 11b therein. The laser chamber 10 is filled with a laser gas containing, for example, an argon gas or a krypton gas as a rare gas, fluorine gas as a halogen gas, and a neon gas as a buffer gas.

The rear mirror 14 is configured by a high reflection mirror, and the output coupling mirror 15 is configured by a partial reflection mirror. The pulse laser beam Out is output from the output coupling mirror 15.

The monitor module 16 includes a beam splitter 17 and a photosensor 18. The beam splitter 17 is located on an optical path of the pulse laser beam Out output from the output coupling mirror 15. The photosensor 18 is located on an optical path of the pulse laser beam Out reflected by the beam splitter 17.

The shutter 19 is located on an optical path of the pulse laser beam Out having passed through the beam splitter 17. The shutter 19 is configured to be able to switch passing and blocking of the pulse laser beam Out to the laser processing apparatus 5.

The laser apparatus 1 further includes a laser control processor 13. The laser control processor 13 is a processor including a memory 13a in which a control program is stored, and a CPU (central processing unit) 13b that executes the control program. The laser control processor 13 is specifically configured or programmed to execute various kinds of processing included in the present disclosure.

### 1.1.2 Configuration of Laser Processing Apparatus

The laser processing apparatus 5 includes an irradiation optical system 50a, a frame 50b, an XYZ stage 501, and a laser processing processor 53.

The irradiation optical system 50a and the XYZ stage 501 are fixed to the frame 50b. A workpiece SUB is supported on a table 502 of the XYZ stage 501.

In FIG. 1, an X direction and a Y direction orthogonal to each other are directions parallel to a surface of the workpiece SUB. A Z direction is a direction perpendicular to the surface of the workpiece SUB and parallel to a traveling direction of the pulse laser beam Out entering the surface of the workpiece SUB. A coordinate system defined by coordinate axes in the X direction, the Y direction, and the Z direction is defined as an XYZ coordinate system.

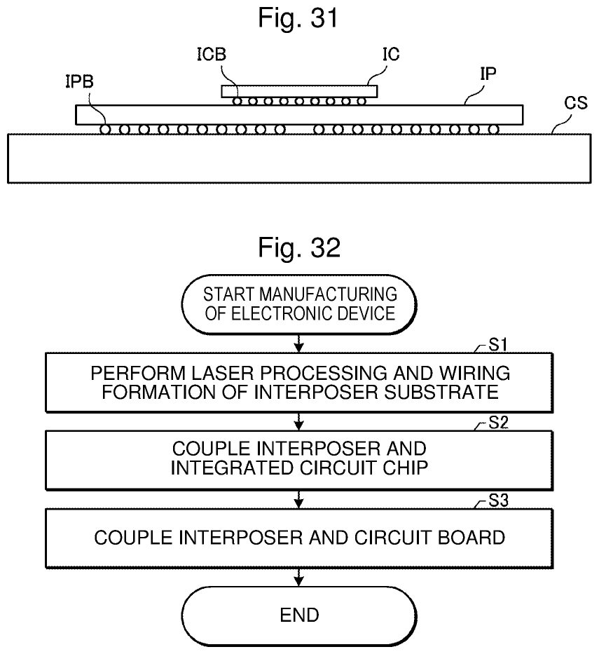

The workpiece SUB is, for example, an interposer substrate for manufacturing an interposer IP that relays an integrated circuit chip IC and a circuit board CS, to be described later with reference to FIG. 31. The interposer substrate is configured by, for example, an electrically insulating material such as a polymer material or a glass material.

The irradiation optical system 50a includes high reflection mirrors 51a, 51b, and 51c, an attenuator 52, a diffractive optical element 63, and a light condensing optical system 67. The high reflection mirrors 51a, 51b, and 51c, the attenuator 52, and the diffractive optical element 63 are housed in a second housing 500. The light condensing optical system 67 also serves as a window of the second housing 500. The second housing 500 is connected to the first housing 100 via an optical path pipe 200. The pulse laser beam Out output from the laser apparatus 1 passes through inside of the optical path pipe 200 and enters the second housing 500.

The high reflection mirror 51a is located on an optical path of the pulse laser beam Out having passed through the inside of the optical path pipe 200. The attenuator 52 is located on an optical path of the pulse laser beam Out reflected by the high reflection mirror 51a. The attenuator 52 includes two partial reflection mirrors 52a and 52b and rotating stages 52c and 52d. The rotating stages 52c and 52d are configured to be able to change a transmittance of the attenuator 52 by changing incident angles of the pulse laser beam Out with respect to the partial reflection mirrors 52a and 52b, respectively.

The high reflection mirror 51b is located on an optical path of the pulse laser beam Out having passed through the attenuator 52, and the high reflection mirror 51c is located on an optical path of the pulse laser beam Out reflected by the high reflection mirror 51b.

The diffractive optical element 63 is located on an optical path of the pulse laser beam Out reflected by the high reflection mirror 51c. The diffractive optical element 63 has many bumps and dents on a surface, and is configured to branch the transmitted pulse laser beam Out into a plurality of optical paths by diffracting the pulse laser beam Out.

The light condensing optical system 67 is located on an optical path of the pulse laser beam Out having passed through the diffractive optical element 63. The light condensing optical system 67 condenses branched light beams of the pulse laser beam Out branched by the diffractive optical element 63. The light condensing optical system 67 has a focal length f₆₇. The light condensing optical system 67 is preferably configured by an Fθ lens so that the branched light beams of the pulse laser beam Out are condensed on a same plane.

The laser processing processor 53 is a processor including a memory 53a in which a control program is stored, and a CPU 53b that executes the control program. The laser processing processor 53 is specifically configured or programmed to execute various kinds of processing included in the present disclosure.

### 1.2 Operation

### 1.2.1 Operation of Laser Apparatus 1

In the laser apparatus 1, the laser control processor 13 receives data and trigger signals of target pulse energy Et from the laser processing processor 53.

The laser control processor 13 sets a voltage of the power supply device 12 based on the target pulse energy Et and transmits a trigger signal to the power supply device 12.

Upon receiving the trigger signal from the laser control processor 13, the power supply device 12 generates a pulsed high voltage and applies it between the discharge electrodes 11a and 11b.

When the high voltage is applied between the discharge electrodes 11a and 11b, discharge occurs between the discharge electrodes 11a and 11b. The laser gas in the laser chamber 10 is excited by the discharge energy and shifts to a high energy level. When the excited laser gas then shifts to a low energy level, light having a wavelength corresponding to the energy level difference is discharged.

The light generated in the laser chamber 10 is output to outside of the laser chamber 10 through the windows 10a and 10b. The light output from the window 10a of the laser chamber 10 is reflected by the rear mirror 14 at a high reflectance and is returned to the laser chamber 10.

The output coupling mirror 15 transmits and outputs a portion of the light output from the window 10b of the laser chamber 10, and reflects the other portion back to the laser chamber 10.

In this way, the light output from the laser chamber 10 reciprocates between the rear mirror 14 and the output coupling mirror 15, and is amplified every time the light passes through a discharge space between the discharge electrodes 11a and 11b. The pulse laser beam Out generated by laser oscillation in this way is output from the output coupling mirror 15.

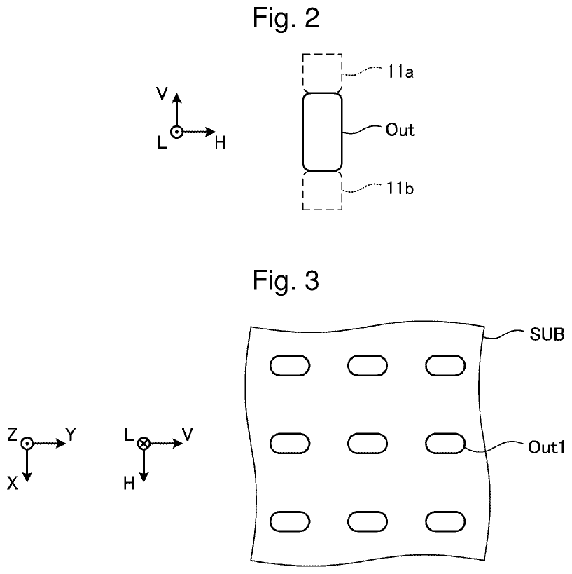

FIG. 2 illustrates a beam cross section perpendicular to an optical path axis of the pulse laser beam Out output from the output coupling mirror 15. FIG. 2 corresponds to a cross sectional view taken along an II-II line in FIG. 1. The beam cross section of the pulse laser beam Out corresponds to a shape of the discharge space between the discharge electrodes 11a and 11b, and has a substantially rectangular shape that is long in a discharge direction between the discharge electrodes 11a and 11b.

An L direction is a traveling direction of the pulse laser beam Out. A V direction is a direction perpendicular to the L direction and parallel to a long side of the beam cross section of the pulse laser beam Out. An H direction is a direction perpendicular to both the L direction and the V direction. The H direction is parallel to a short side of the beam cross section of the pulse laser beam Out. The V direction and the H direction correspond to first and second directions in the present disclosure, respectively. A coordinate system defined by coordinate axes in the L direction, the V direction, and the H direction is defined as an LVH coordinate system.

Since the LVH coordinate system is defined with reference to the pulse laser beam Out, when the pulse laser beam Out is reflected, a relationship between the LVH coordinate system and the XYZ coordinate system described with reference to FIG. 1 changes and the LVH coordinate system itself is inverted. For example, when the pulse laser beam Out is reflected at a right angle by the high reflection mirror 51a, the traveling direction of the pulse laser beam Out is rotated at a right angle around an H axis. In this case, each of the L direction and the V direction is rotated at the right angle to the XYZ coordinate system, and further, the V direction is reversed. However, it is assumed that the L direction, the V direction, and the H direction are not changed by a projection optical system 68 to be described later.

Referring back to FIG. 1, the monitor module 16 detects pulse energy of the pulse laser beam Out output from the output coupling mirror 15. The monitor module 16 transmits data of the detected pulse energy to the laser control processor 13.

The laser control processor 13 feedback-controls a set voltage of the power supply device 12 based on the data of the pulse energy received from the monitor module 16 and data of the target pulse energy Et received from the laser processing processor 53.

### 1.2.2 Operation of Laser Processing Apparatus 5

The XYZ stage 501 is adjusted so that the workpiece SUB is positioned at a position at the focal length f₆₇ from the light condensing optical system 67.

The pulse laser beam Out output from the laser apparatus 1 passes through the inside of the optical path pipe 200 and enters the laser processing apparatus 5. The pulse laser beam Out is reflected by the high reflection mirror 51a, is transmitted through the attenuator 52, and is then sequentially reflected by the high reflection mirrors 51b and 51c. The laser processing processor 53 sets a target value for the transmittance of the attenuator 52, and controls the rotating stages 52c and 52d based on the target value.

The pulse laser beam Out reflected by the high reflection mirror 51c is branched into a plurality of optical paths by the diffractive optical element 63, and each of branched light beams is condensed on a surface of the workpiece SUB by the light condensing optical system 67. When the workpiece SUB is irradiated with the branched light beams of the pulse laser beam Out, the surface of the workpiece SUB is ablated and subjected to laser processing.

### 1.3 Problem of Comparative Example

FIG. 3 illustrates a cross section of branched light beams Out1 of the pulse laser beam Out entering the workpiece SUB in the comparative example. In an example illustrated in FIG. 3, the branched light beams Out1 of the pulse laser beam Out branched by the diffractive optical element 63 enter positions corresponding to respective apexes of a square lattice on the surface of the workpiece SUB. A shape and an arrangement of the branched light beams Out1 vary depending on a design of the diffractive optical element 63. By irradiating the workpiece SUB with a large number of narrow branched light beams Out1 condensed by the light condensing optical system 67, a large number of fine holes can be formed in the workpiece SUB. The holes may be through-holes that penetrate the workpiece SUB.

However, a cross-sectional shape of the branched light beams Out1 condensed by the light condensing optical system 67 may not be same as the design of the diffractive optical element 63. For example, even if the diffractive optical element 63 is designed such that the cross-sectional shape of the branched light beams Out1 becomes truly circular, the cross-sectional shape may be an ellipse shape or an oval shape that is longer in the V direction than in the H direction in the workpiece SUB as illustrated in FIG. 3. In this case, desired laser processing may not be realized.

In the embodiment described below, by controlling beam divergences BDV and BDH of the pulse laser beam Out entering the diffractive optical element 63, the cross-sectional shape of the branched light beams Out1 entering the workpiece SUB is brought closer to a desired shape.

### 2. Laser Processing System Including Divergence Adjuster 54

### 2.1 Configuration

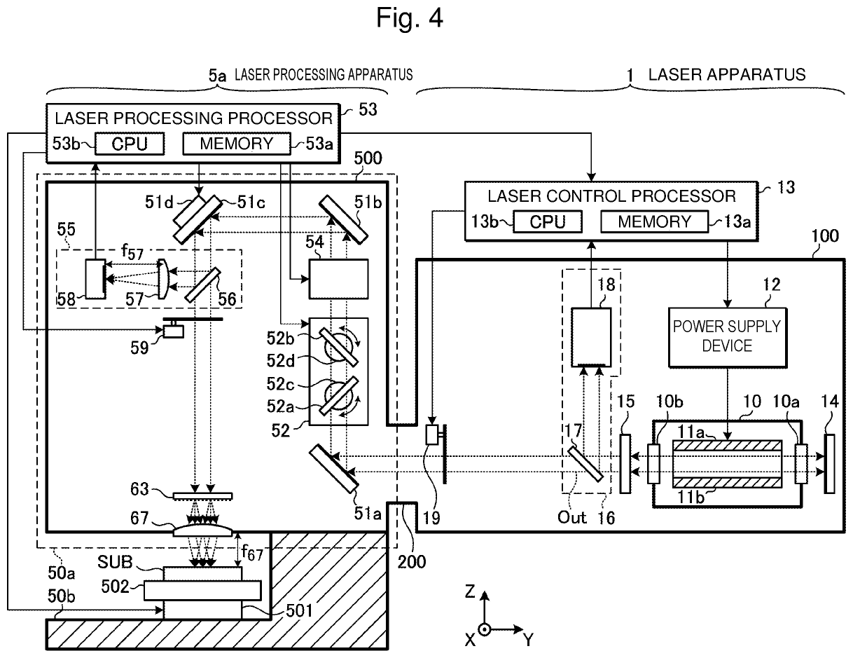

FIG. 4 schematically illustrates a configuration of a laser processing system in a first embodiment. In the first embodiment, a laser processing apparatus 5a included in the laser processing system includes, in addition to the components illustrated in FIG. 1, an actuator 51d, a divergence adjuster 54, a measuring instrument 55, and a shutter 59.

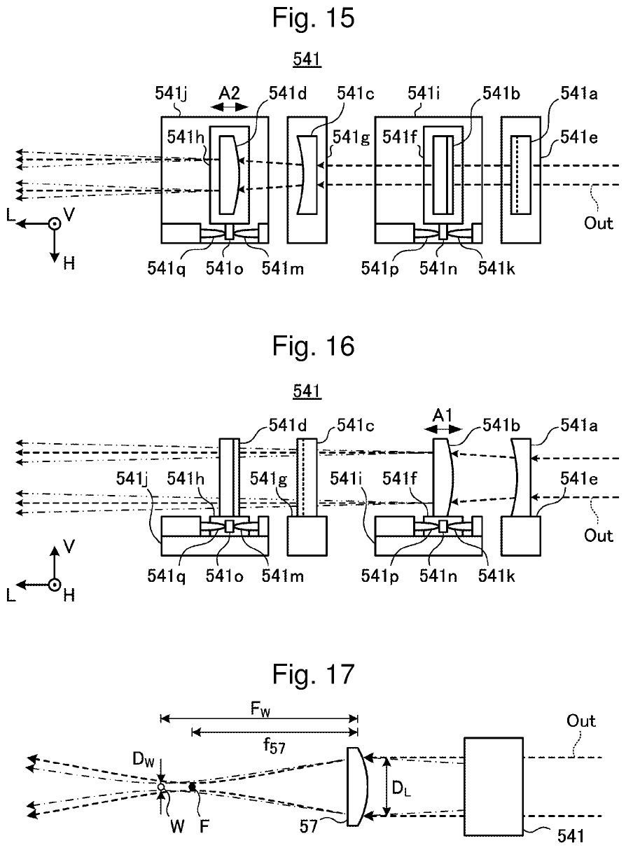

The divergence adjuster 54 is configured to be able to adjust the beam divergence BDV in the V direction and the beam divergence BDH in the H direction of the pulse laser beam Out. A specific configuration of the divergence adjuster 54 will be described later with reference to FIGS. 15 to 26. While the divergence adjuster 54 is disposed between the attenuator 52 and the high reflection mirror 51b in an example illustrated in FIG. 4, the divergence adjuster 54 may be disposed at any position on an optical path of the pulse laser beam Out between the high reflection mirror 51a and the measuring instrument 55.

The actuator 51d is attached to the high reflection mirror 51c, and is configured to be able to change a posture of the high reflection mirror 51c. By changing the posture of the high reflection mirror 51c, the traveling direction of the pulse laser beam Out reflected by the high reflection mirror 51c is changed. By adjusting the traveling direction of the pulse laser beam Out, beam pointings BPV and BPH are adjusted. The high reflection mirror 51c and the actuator 51d configure a beam steering device. The beam steering device may be disposed at any position on an optical path of the pulse laser beam Out between the inside of the optical path pipe 200 and the measuring instrument 55, but is more desirably disposed on an optical path of the pulse laser beam Out between the divergence adjuster 54 and the measuring instrument 55.

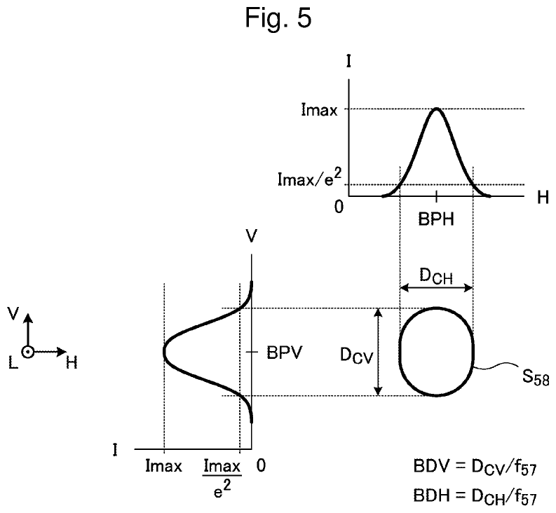

The measuring instrument 55 includes a beam splitter 56, a convex lens 57, and an image sensor 58. The beam splitter 56 is located on an optical path of the pulse laser beam Out having passed through both the divergence adjuster 54 and the beam steering device. The convex lens 57 is located on an optical path of the pulse laser beam Out reflected by the beam splitter 56. The convex lens 57 has a focal length f₅₇. The focal length f₅₇ may be greater than the focal length f₆₇ of the light condensing optical system 67. The image sensor 58 is located on a focal plane of the convex lens 57 on an optical path of the pulse laser beam Out having passed through the convex lens 57. Here, the convex lens 57 may be a combination lens having the focal length f₅₇, in which a concave lens and a convex lens are combined. The measuring instrument 55 is configured to be able to measure the beam divergences BDV and BDH and the beam pointings BPV and BPH of the pulse laser beam Out having passed through both the divergence adjuster 54 and the beam steering device. Measurement of the beam divergences BDV and BDH and the beam pointings BPV and BPH will be described later with reference to FIG. 5.

The shutter 59 is located on an optical path of the pulse laser beam Out having passed through the beam splitter 56. The shutter 59 is configured to be able to switch passing and blocking of the pulse laser beam Out to the diffractive optical element 63 and the workpiece SUB.

FIG. 5 illustrates a beam cross section S₅₈ of the pulse laser beam Out measured by the image sensor 58 included in the measuring instrument 55, together with light intensity distributions in the V direction and the H direction. A total width in the V direction of a portion having light intensity I equal to or higher than 1/e² of a peak value Imax of the light intensity I is defined as a spot diameter D_{cv} in the V direction, and a total width in the H direction of the portion is defined as a spot diameter D_{CH} in the H direction. Alternatively, a half value or 1/e may be used instead of 1/e². Note that e is a Napier's constant. In the present disclosure, a spot diameter is a diameter of a beam cross section at a focal position. A beam waist diameter to be described later is a diameter of the beam cross section at a beam waist position, and may be different from the spot diameter.

In the present disclosure, a beam divergence is defined as a value for which a beam width at the focal position is divided by a focal length. The beam divergences BDV and BDH in the V direction and the H direction are given by equations below.

$$\begin{matrix}BDV = {D}_{CV} / {f}_{57} \\ BDH = {D}_{CH} / {f}_{57}\end{matrix}$$

The beam divergences BDV and BDH correspond to first and second beam divergences in the present disclosure, respectively.

In the present disclosure, the beam pointings BPV and BPH are defined as central positions in the V direction and the H direction of the beam cross section at the focal position. The central position may be, for example, a centroid position of the light intensity distribution in each of the V direction and the H direction, or may be a center position of each of the spot diameters D_{CV} and D_{CH}.

### 2.2 Operation

### 2.2.1 Main Flow

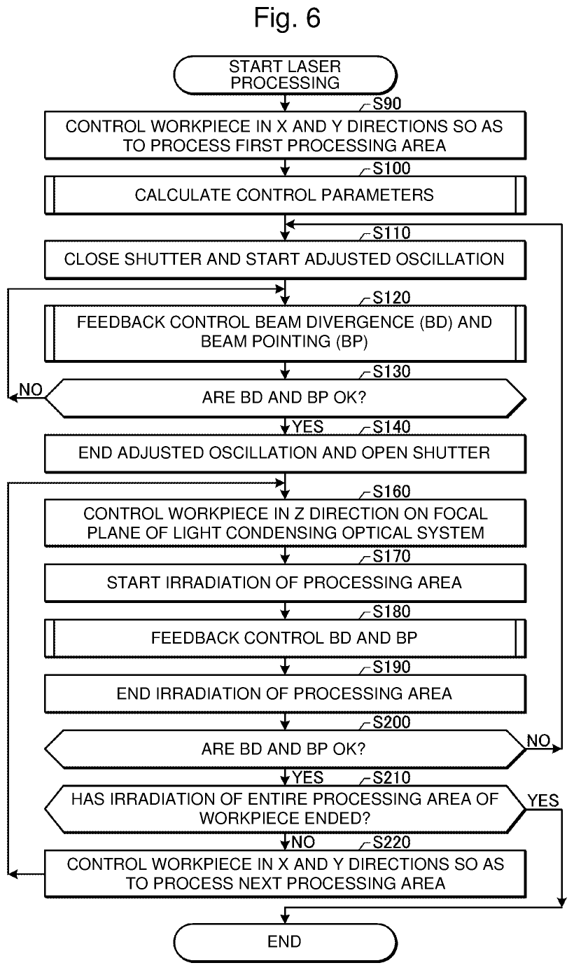

FIG. 6 is a flowchart illustrating a laser processing method in the first embodiment. The laser processing processor 53 controls the laser processing apparatus 5a as described below to perform laser processing by a step-and-repeat method.

In S90, the laser processing processor 53 controls a position of the workpiece SUB in the X direction and the Y direction so that a first processing area of the workpiece SUB is processed with the pulse laser beam Out when the first processing area is irradiated with the pulse laser beam Out.

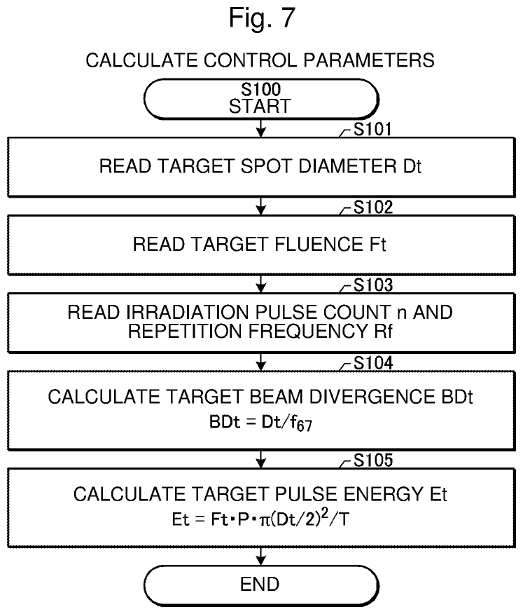

In 5100, the laser processing processor 53 calculates various kinds of control parameters. Details of 5100 will be described later with reference to FIG. 7.

In 5110, the laser processing processor 53 closes the shutter 59, transmits a trigger signal to the laser apparatus 1, and starts adjusted oscillation.

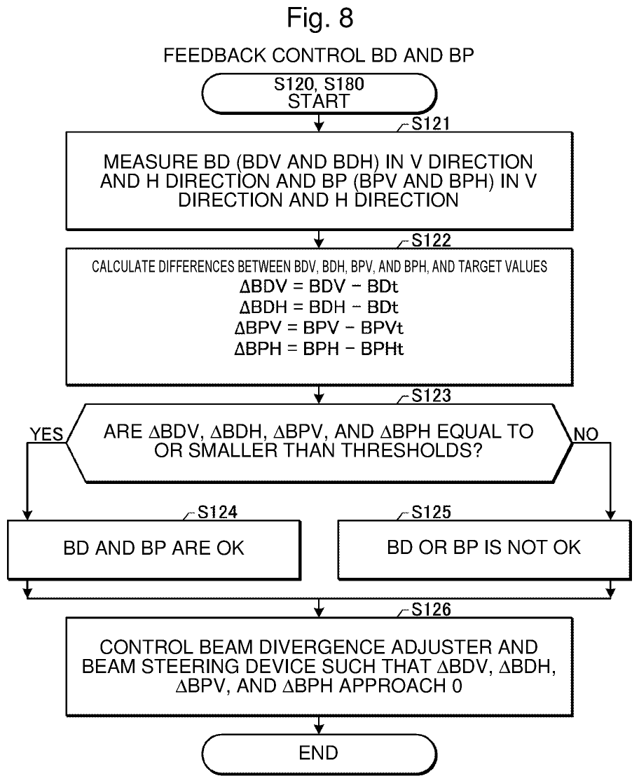

In 5120, the laser processing processor 53 feedback-controls the beam divergences BDV and BDH and the beam pointings BPV and BPH. In FIG. 6, the beam divergence and the beam pointing may be abbreviated as BD and BP, respectively. Details of 5120 will be described later with reference to FIG. 8.

In 5130, the laser processing processor 53 determines whether or not the beam divergences BDV and BDH and the beam pointings BPV and BPH are OK. This determination is made based on a result of the processing of S120 illustrated in FIG. 8.

When the beam divergences BDV and BDH and the beam pointings BPV and BPH are OK (S130: YES), the laser processing processor 53 advances the processing to S140. When they are not OK (S130: NO), the laser processing processor 53 returns the processing to S120.

In 5140, the laser processing processor 53 ends the adjusted oscillation and opens the shutter 59. As described above, the pulse laser beam Out is blocked until measurement results of the beam divergences BDV and BDH and the beam pointings BPV and BPH fall within an allowable range.

In S160, the laser processing processor 53 controls the position of the workpiece SUB in the Z direction so that the workpiece SUB is positioned on a focal plane of the light condensing optical system 67.

In S170, the laser processing processor 53 starts irradiation of a present processing area with the pulse laser beam Out.

In S180, the laser processing processor 53 feedback-controls the beam divergences BDV and BDH and the beam pointings BPV and BPH. The processing of S180 is the same as the processing of S120 and the details will be described later with reference to FIG. 8.

In S190, the laser processing processor 53 ends the irradiation of the present processing area with the pulse laser beam Out when the present processing area is irradiated with the pulse laser beam Out having an irradiation pulse count n determined in 5100.

In S200, the laser processing processor 53 determines whether or not the beam divergences BDV and BDH and the beam pointings BPV and BPH are OK. When the beam divergences BDV and BDH and the beam pointings BPV and BPH are OK (S200: YES), the laser processing processor 53 advances the processing to S210. When they are not OK (S200: NO), the laser processing processor 53 returns the processing to S110.

In S210, the laser processing processor 53 determines whether or not the irradiation of the entire processing area of the workpiece SUB has been ended. When the irradiation of the entire processing area has been ended (S210: YES), the laser processing processor 53 ends the processing of this flow chart. When an unprocessed area remains (S210: NO), the laser processing processor 53 advances the processing to S220.

In S220, the laser processing processor 53 controls the position of the workpiece SUB in the X direction and the Y direction so that the subsequent processing area is processed by the pulse laser beam Out. After S220, the laser processing processor 53 returns the processing to S160.

### 2.2.2 Calculation of Control Parameters

FIG. 7 is a flowchart illustrating details of the processing of calculating control parameters. The processing illustrated in FIG. 7 corresponds to a subroutine of 5100 illustrated in FIG. 6.

In S101, the laser processing processor 53 reads a target spot diameter Dt in the workpiece SUB from the memory 53a. The target spot diameter Dt is a target value of the spot diameter in the V direction and the spot diameter in the H direction. While a case where the same target spot diameter Dt is used for the V direction and the H direction is described here, different target spot diameters may be used.

In S102, the laser processing processor 53 reads a target fluence Ft from the memory 53a. A fluence is an energy density of the pulse laser beam Out on the surface of the workpiece SUB.

In S103, the laser processing processor 53 reads the irradiation pulse count n and a repetition frequency Rf in one processing area from the memory 53a. In S101 to S103, various kinds of data are read from the memory 53a, however, data received from an unillustrated computer device may be read or data input by an operator may be read.

In S104, the laser processing processor 53 calculates a target divergence BDt by a following equation.

$$BDt = Dt / {f}_{67}$$

The target divergence BDt is a target value of the beam divergences BDV and BDH. While a case where the same target value is set for the V direction and the H direction is described here, different target values may be set. However, it is desirable that a difference between the target values of the beam divergences BDV and BDH in the V direction and the H direction of the pulse laser beam Out having passed through the divergence adjuster 54 is smaller than a difference between the beam divergences in the V direction and the H direction of the pulse laser beam Out entering the divergence adjuster 54. The beam divergences in the V direction and the H direction of the pulse laser beam Out entering the divergence adjuster 54 correspond to third and fourth beam divergences in the present disclosure.

In S105, the laser processing processor 53 calculates the target pulse energy Et by a following equation.

$$E t = Ft \cdot P \cdot S / T$$

Here, P is the number of processing points in one processing area. A reference character S denotes area of a beam cross section of one processing point at a focal position of the light condensing optical system 67, and is given by a following equation using the target spot diameter Dt.

$$S = {π ( Dt / 2 )}^{2}$$

A reference character T denotes a transmittance of the optical system in the laser processing apparatus 5a, and is given by a following equation.

$$T = Ta \cdot To$$

Here, a reference character Ta denotes a transmittance of the attenuator 52 and a reference character To denotes a transmittance of optical elements other than the attenuator 52.

After S105, the laser processing processor 53 ends the processing of this flowchart and returns to the processing illustrated in FIG. 6.

### 2.2.3 Feedback Control of Beam Divergences BDV and BDH and Beam Pointings BPV and BPH

FIG. 8 is a flowchart illustrating details of the processing of feedback-controlling the beam divergences BDV and BDH and the beam pointings BPV and BPH. The processing illustrated in FIG. 8 corresponds to a subroutine of S120 and S180 illustrated in FIG. 6.

In S121, the laser processing processor 53 measures the beam divergences BDV and BDH in the V direction and the H direction, and the beam pointings BPV and BPH in the V direction and the H direction by the measuring instrument 55.

In 5122, the laser processing processor 53 calculates differences ΔBDV, ΔBDH, ΔBPV, and ΔBPH between the beam divergences BDV and BDH and the beam pointings BPV and BPH and their target values by following equations.

$$\begin{matrix}Δ BDV = BDV - BDt \\ Δ BDH = BDH - BDt \\ Δ BPV = BPV - BPVt \\ Δ BPH = BPH - BPHt\end{matrix}$$

Reference characters BPVt and BPHt are the target values for the beam pointings BPV and BPH, respectively.

In S123, the laser processing processor 53 determines whether or not the differences ΔBDV, ΔBDH, ΔBPV, and ΔBPH are equal to or smaller than respective thresholds. When all of the differences ΔBDV, ΔBDH, ΔBPV, and ΔBPH are equal to or smaller than the respective thresholds (S123: YES), the laser processing processor 53 advances the processing to S124. When any of the differences ΔBDV, ΔBDH, ΔBPV, and ΔBPH exceeds the threshold (S123: NO), the laser processing processor 53 advances the processing to S125.

In S124, the laser processing processor 53 stores a flag indicating that the beam divergences BDV and BDH and the beam pointings BPV and BPH are OK in the memory 53a.

In S125, the laser processing processor 53 stores a flag indicating that either the beam divergences BDV and BDH or the beam pointings BPV and BPH are not OK in the memory 53a.

In S130 and S200 illustrated in FIG. 6, the flags are read and the determination is made.

After S124 or S125, in S126, the laser processing processor 53 controls the divergence adjuster 54 and the beam steering device so that the differences ΔBDV, ΔBDH, ΔBPV, and ΔBPH approach 0.

After S126, the laser processing processor 53 ends the processing of this flowchart and returns to the processing illustrated in FIG. 6.

### 2.3 Effect

(1) According to the first embodiment, the laser processing system includes the divergence adjuster 54 that adjusts the beam divergence BDV in the V direction and the beam divergence BDH in the H direction of the pulse laser beam Out output from the laser apparatus 1. The beam divergences BDV and BDH of the pulse laser beam Out having passed through the divergence adjuster 54 are measured by the measuring instrument 55. The laser processing processor 53 controls the divergence adjuster 54 so that the beam divergences BDV and BDH approach their respective target values based on the measurement result by the measuring instrument 55. The pulse laser beam Out having passed through the measuring instrument 55 is branched by the diffractive optical element 63. Thus, the cross-sectional shape of the branched light beams that are branched by the diffractive optical element 63 and enter the workpiece SUB can be brought closer to a desired shape.

In addition, even when a temperature of the optical element included in the laser apparatus 1 is changed or the discharge electrodes 11a and 11b are exhausted and the beam divergence of the pulse laser beam Out output from the laser apparatus 1 is changed, the beam divergences BDV and BDH of the pulse laser beam Out entering the diffractive optical element 63 are stabilized by the divergence adjuster 54. As a result, the cross-sectional shape of the branched light beams with which the workpiece SUB is irradiated is stabilized, and the shape of the holes to be processed on the workpiece SUB is stabilized.

(2) According to the first embodiment, the difference between the target values of the beam divergences BDV and BDH in the V direction and the H direction of the pulse laser beam Out having passed through the divergence adjuster 54 is smaller than the difference between the beam divergences in the V direction and the H direction of the pulse laser beam Out entering the divergence adjuster 54. Accordingly, a dimensional difference between the long side and the short side in the cross-sectional shape of the branched light beams with which the workpiece SUB is irradiated is reduced.

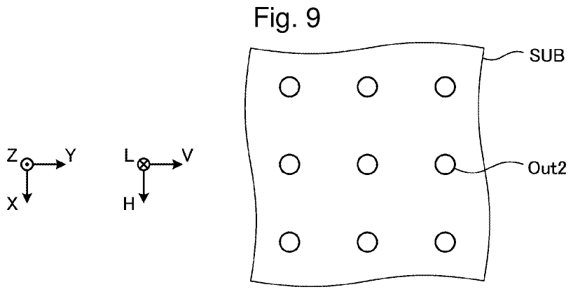

FIG. 9 illustrates a cross section of branched light beams Out2 of the pulse laser beam Out entering the workpiece SUB in the first embodiment. When the same target spot diameter Dt is set for the V direction and the H direction, the cross-sectional shape of the branched light beams Out2 with which the workpiece SUB is irradiated becomes closer to a circular shape. As a result, the shape of the holes to be processed on the workpiece SUB may be closer to a circular shape.

(3) According to the first embodiment, the laser processing system further includes the beam steering device that adjusts the traveling direction of the pulse laser beam Out. The beam steering device is configured by the actuator 51d and the high reflection mirror 51c, and is disposed on the optical path of the pulse laser beam Out between the laser apparatus 1 and the diffractive optical element 63. The beam pointings BPV and BPH of the pulse laser beam Out having passed through the beam steering device are measured by the measuring instrument 55. The laser processing processor 53 controls the beam steering device so that the beam pointings BPV and BPH approach the target value, based on the measurement result by the measuring instrument 55. Accordingly, a desired position on the workpiece SUB can be irradiated with the branched light beams Out2. In addition, even when the temperature of the optical element included in the laser apparatus 1 is changed or the discharge electrodes 11a and 11b are exhausted and the beam pointing of the pulse laser beam Out output from the laser apparatus 1 is changed, the beam pointings BPV and BPH of the pulse laser beam Out entering the diffractive optical element 63 are stabilized by the beam steering device. As a result, the position of the branched light beams Out2 with which the workpiece SUB is irradiated is stabilized, and the position of the holes to be processed on the workpiece SUB is stabilized.

(4) According to the first embodiment, the laser processing system further includes the shutter 59 configured to be able to switch passing and blocking of the pulse laser beam Out. The shutter 59 is disposed on the optical path of the pulse laser beam Out having passed through the measuring instrument 55. The laser processing processor 53 controls the shutter 59 so that the pulse laser beam Out is blocked until the measurement results of the beam divergences BDV and BDH by the measuring instrument 55 fall within the respective allowable ranges including the respective target values. Accordingly, since the workpiece SUB is processed after the measurement results fall within the allowable ranges, high processing accuracy can be obtained.

(5) According to the first embodiment, the laser processing system further includes the light condensing optical system 67 disposed on the optical path of the pulse laser beam Out having passed through the diffractive optical element 63. The workpiece SUB is located on the focal plane of the light condensing optical system 67. Accordingly, it is possible to perform fine processing by condensing the branched light beams branched by the diffractive optical element 63.

(6) According to the first embodiment, the laser apparatus 1 included in the laser processing system includes the optical resonator housed in the first housing 100. The divergence adjuster 54 and the diffractive optical element 63 are housed in the second housing 500. Accordingly, since the beam divergences BDV and BDH are adjusted in the laser processing apparatus 5a, even when the beam divergence of the pulse laser beam Out output from the laser apparatus 1 is changed, the cross-sectional shape of the branched light beams with which the workpiece SUB is irradiated can be stabilized.

In other respects, the first embodiment is similar to the comparative example.

### 2.4 Laser Processing System with Laser Apparatus 1b Including Divergence Adjuster 20

### 2.4.1 Configuration

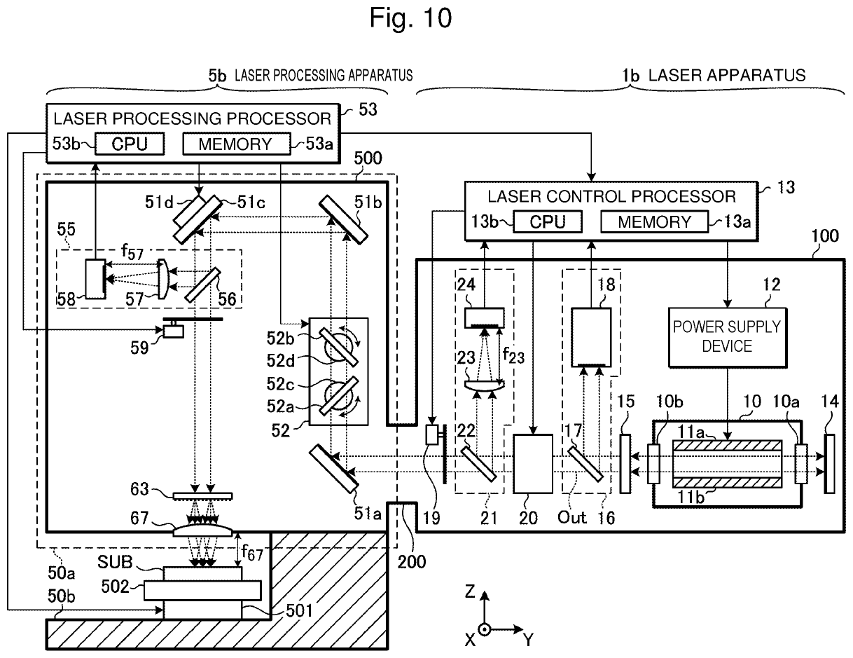

FIG. 10 schematically illustrates a configuration of a laser processing system in a modification. In FIG. 10, a divergence adjuster 20 and a measuring instrument 21 are included in a laser apparatus 1b, and these components are housed in the first housing 100 together with the optical resonator. A laser processing apparatus 5b may not include the divergence adjuster 54.

A configuration of the divergence adjuster 20 is similar to the configuration of the divergence adjuster 54, and will be described later with reference to FIGS. 15 to 26.

The measuring instrument 21 includes a beam splitter 22, a convex lens 23, and an image sensor 24. The beam splitter 22 is located on an optical path of the pulse laser beam Out having passed through the divergence adjuster 20. The convex lens 23 is located on an optical path of the pulse laser beam Out reflected by the beam splitter 22. The convex lens 23 has a focal length f₂₃. The focal length f₂₃ may be greater than the focal length f₆₇ of the light condensing optical system 67. The image sensor 24 is located on a focal plane of the convex lens 23 on an optical path of the pulse laser beam Out having passed through the convex lens 23. Here, the convex lens 23 may be a combination lens having the focal length f₂₃, in which a concave lens and a convex lens are combined. The measuring instrument 21 is configured to be able to measure the beam divergences BDV and BDH.

### 2.4.2 Operation

The laser control processor 13 feedback-controls the divergence adjuster 20 based on the beam divergences BDV and BDH measured by the measuring instrument 21 and the target divergence BDt obtained by calculation.

The laser processing processor 53 feedback-controls the actuator 51d based on the beam pointings BPV and BPH measured by the measuring instrument 55 and the target values BPVt and BPHt of the beam pointings BPV and BPH obtained by calculation.

In this way, the modification is different from the description with reference to FIGS. 4 to 9 in that the beam divergences BDV and BDH are measured and controlled in the laser apparatus 1b and the beam pointings BPV and BPH are measured and controlled in the laser processing apparatus 5b. Other points may be the same as the description with reference to FIGS. 4 to 9.

Since the measuring instrument 55 can also measure the beam divergences BDV and BDH, the laser processing may be performed while confirming that the beam divergences BDV and BDH measured by the measuring instrument 55 are OK. The adjusted oscillation may be performed when either one of the beam divergences BDV and BDH measured by the measuring instrument 55 is not OK.

As yet another modification, the measuring instrument 21 may be removed from the configuration of FIG. 10. The divergence adjuster 20 may be controlled based on the beam divergences BDV and BDH measured by the measuring instrument 55.

### 2.4.3 Effect

(7) According to the modification, the laser apparatus 1b included in the laser processing system includes the optical resonator and the divergence adjuster 20 housed in the first housing 100. The diffractive optical element 63 is housed in the second housing 500. Accordingly, since the pulse laser beam Out with the adjusted beam divergences BDV and BDH is output from the laser apparatus 1b, it is possible to suppress complication of the configuration of the laser processing apparatus 5b.

In other respects, the modification is similar to the description with reference to FIGS. 4 to 9.

### 3. Laser Processing System Having Mask 65 Disposed on Optical Path of Branched Light Beams by Diffractive Optical Element 63 and Transferring Image of Mask 65 to Workpiece SUB

### 3.1 Configuration and Operation

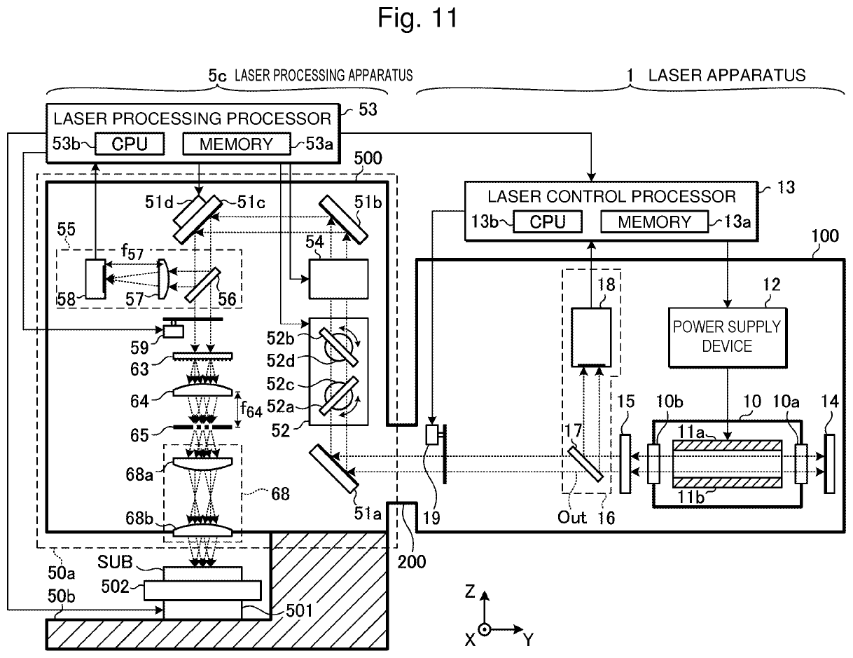

FIG. 11 schematically illustrates a configuration of a laser processing system in a second embodiment. In the second embodiment, a laser processing apparatus Sc included in the laser processing system includes a light condensing optical system 64 instead of the light condensing optical system 67 illustrated in FIG. 4, and further includes a mask 65 and the projection optical system 68.

The light condensing optical system 64 is disposed on an optical path of the pulse laser beam Out having passed through the diffractive optical element 63 inside the second housing 500, and has a focal length f₆₄. In other respects, the light condensing optical system 64 is similar to the light condensing optical system 67 described with reference to FIG. 4.

The mask 65 is located on a focal plane of the light condensing optical system 64 on an optical path of the pulse laser beam Out having passed through the light condensing optical system 64.

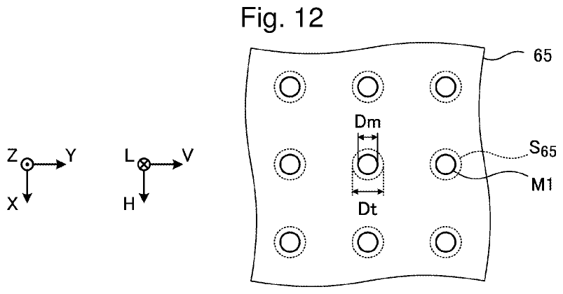

FIG. 12 is a plan view of the mask 65 in the second embodiment. The mask 65 has many circular openings M1, and a diameter of each opening M1 is Dm. It is desirable that each opening M1 is truly circular. The branched light beams of the pulse laser beam Out branched by the diffractive optical element 63 are condensed by passing through the light condensing optical system 64 so that cross sections S₆₅ of the branched light beams at the position of the mask 65 overlap with the respective positions of the openings M1. Alignment of the cross sections S₆₅ of the branching light beams with the openings M1 is adjusted by the beam steering device. A diameter of each cross section S₆₅ of the branched light beam is adjusted by the divergence adjuster 54 so as to approach the target spot diameter Dt. The target spot diameter Dt is set to satisfy Equation 1 below.

$$Dm \leq Dt \leq K \cdot Dm … \qquad Equation 1$$

Here, it is preferable that K is equal to or larger than 1.1 and is equal to or smaller than 1.4.

Referring back to FIG. 11, the projection optical system 68 is located on an optical path of the pulse laser beam Out having passed through the mask 65, and includes first and second lenses 68a and 68b. The second lens 68b also serves as a window of the second housing 500. The projection optical system 68 projects an image of the mask 65 onto the workpiece SUB. A beam diameter of each of the branched light beams in the workpiece SUB is obtained by multiplying the diameter Dm of each opening M1 of the mask 65 by a magnification of the projection optical system 68.

### 3.2 Effect

(8) According to the second embodiment, the laser processing system includes the light condensing optical system 64 disposed on the optical path of the pulse laser beam Out having passed through the diffractive optical element 63, the mask 65 disposed on the focal plane of the light condensing optical system 64 and provided with a plurality of openings, and the projection optical system 68 disposed on the optical path of the pulse laser beam Out having passed through the mask 65. Accordingly, an image of the mask 65 can be projected onto the workpiece SUB by the projection optical system 68, and a cross-sectional shape of the branched light beam of the pulse laser beam Out with which the workpiece SUB is irradiated can be brought closer to a desired shape. Further, according to the second embodiment, by making the shape of the opening M1 of the mask 65 be truly circular, the cross-sectional shape of the branched light beam of the pulse laser beam Out with which the workpiece SUB is irradiated can be turned to a shape closer to a true circle than in the first embodiment.

(9) According to the second embodiment, the light condensing optical system 64 condenses the branched light beams so that the cross sections of the branched light beams of the pulse laser beam Out branched by the diffractive optical element 63 overlap the respective openings M1. Accordingly, since each of the branched light beams branched by the diffractive optical element 63 is condensed by the light condensing optical system 64 at the position of the opening M1 of the mask 65, it is possible to reduce loss of light in the mask 65 and to improve utilization efficiency of the light.

In addition, by controlling the beam divergences BDV and BDH of the pulse laser beam Out entering the diffractive optical element 63, a spot shape when each of the branched light beams branched by the diffractive optical element 63 is condensed on the mask 65 by the light condensing optical system 64 can be brought closer to the shape of the opening M1 of the mask 65, and the utilization efficiency of the light can be improved.

Further, by controlling the beam pointings BPV and BPH of the pulse laser beam Out entering the diffractive optical element 63, the position of the branched light beam entering the mask 65 can be stabilized, and the utilization efficiency of the light can be improved.

In other respects, the second embodiment is similar to the first embodiment.

### 4. Laser Processing System Making Light Having Passed Through Mask 61 Enter Diffractive Optical Element 63

### 4.1 Configuration and Operation

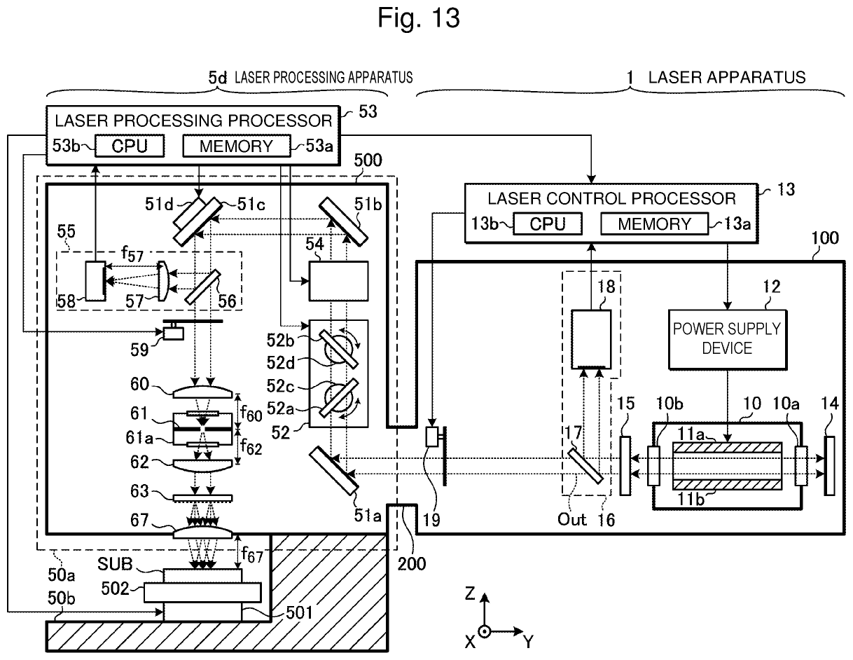

FIG. 13 schematically illustrates a configuration of a laser processing system in a third embodiment. In the third embodiment, a laser processing apparatus 5d included in the laser processing system includes a light condensing lens 60, a mask 61, and a collimator optical system 62, in addition to the components illustrated in FIG. 4.

The light condensing lens 60 is located on an optical path of the pulse laser beam Out between the shutter 59 and the diffractive optical element 63, and has a focal length f₆₀. The light condensing lens 60 is not limited to a single lens, and may include a plurality of lenses.

The mask 61 is located at a focal point of the light condensing lens 60 on an optical path of the pulse laser beam Out having passed through the light condensing lens 60.

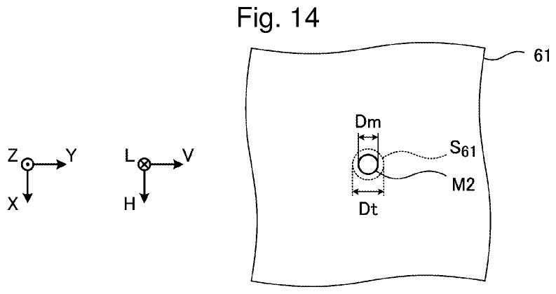

FIG. 14 is a plan view of the mask 61 in the third embodiment. The mask 61 has one circular opening M2 and a diameter of the opening M2 is Dm. It is desirable that the opening M2 is truly circular. The pulse laser beam Out is condensed at a position of the mask 61 by the light condensing lens 60. The beam steering device is controlled so that a cross section S₆₁ of the pulse laser beam Out in the mask 61 coincides with a position of the opening M2. The divergence adjuster 54 is controlled so that a diameter of the cross section S₆₁ approaches the target spot diameter Dt. The target spot diameter Dt is set to satisfy Equation 1 described above.

Referring back to FIG. 13, when the pulse laser beam Out is condensed on the opening of the mask 61, in a case where the mask 61 is in the air, plasma may be generated at the opening of the mask 61 causing breakdown. Therefore, the mask 61 may be disposed inside a vacuum chamber 61a having a window to the light condensing lens 60 and a window to the collimator optical system 62.

In addition, an unillustrated refrigerant jacket may be attached to the mask 61 in order to prevent the mask 61 from becoming high in temperature. Further, as a material of the mask 61, a refractory metal such as tungsten or molybdenum may be used.

The collimator optical system 62 is located on an optical path of the pulse laser beam Out having passed through the mask 61. The collimator optical system 62 has a focal length f₆₂, and the mask 61 is located at a front focal point of the collimator optical system 62. The collimator optical system 62 outputs the pulse laser beam Out having passed through the opening M2 of the mask 61 as parallel light, and makes it enter the diffractive optical element 63. The collimator optical system 62, the diffractive optical element 63, and the light condensing optical system 67 project an image of the mask 61 to a plurality of positions on the workpiece SUB. A beam diameter of each of the branched light beams in the workpiece SUB is obtained by multiplying the diameter Dm of the opening M2 of the mask 61 by the magnification of the projection optical system configured by the collimator optical system 62, the diffractive optical element 63, and the light condensing optical system 67.

### 4.2 Effect

(10) According to the third embodiment, the laser processing system includes the light condensing lens 60 disposed on the optical path of the pulse laser beam Out having passed through the measuring instrument 55 and configured to condense the pulse laser beam Out, the mask 61 disposed on the optical path of the pulse laser beam Out having passed through the light condensing lens 60, and the collimator optical system 62 disposed on the optical path of the pulse laser beam Out between the mask 61 and the diffractive optical element 63. Accordingly, since the pulse laser beam Out having passed through the light condensing lens 60 is just condensed on the opening M2 of the mask 61, a light condensing position of the pulse laser beam Out is easily aligned.

(11) According to the third embodiment, the mask 61 is located at the focal point of the light condensing lens 60. Thus, the mask 61 and the light condensing lens 60 are more easily aligned.

(12) According to the third embodiment, the laser processing system includes the light condensing optical system 67 disposed on the optical path of the pulse laser beam Out having passed through the diffractive optical element 63, and the collimator optical system 62, the diffractive optical element 63, and the light condensing optical system 67 project the image of the mask 61 to a plurality of positions on the workpiece SUB. Accordingly, since the image of the mask 61 is projected on the workpiece SUB, the cross-sectional shape of the branched light beam of the pulse laser beam Out with which the workpiece SUB is irradiated can be brought closer to a desired shape. Further, according to the third embodiment, by making the shape of the opening M2 of the mask 61 be truly circular, the cross-sectional shape of the branched light beam of the pulse laser beam Out with which the workpiece SUB is irradiated can be turned to a shape closer to a true circle than the first embodiment.

### 5. Details of Divergence Adjuster

Details of a divergence adjuster will be described with reference to FIGS. 15 to 26. Each of the divergence adjusters described below can be used as the divergence adjuster 54 described with reference to FIG. 4, FIG. 11, or FIG. 13, or the divergence adjuster 20 described with reference to FIG. 10.

### 5.1 Divergence Adjuster 541 that Adjusts Beam Divergence Angle

### 5.1.1 Configuration and Operation

FIG. 15 and FIG. 16 schematically illustrate a first example of a divergence adjuster. FIG. 15 is a view of a divergence adjuster 541 in a −V direction, and FIG. 16 is a view in a −H direction.

In the first example, the divergence adjuster 541 includes two sets of cylindrical lenses. The two sets of cylindrical lenses include a set of a concave lens 541a and a convex lens 541b and a set of a concave lens 541c and a convex lens 541d.

The concave lenses 541a and 541c are fixed by holders 541e and 541g, respectively. The convex lenses 541b and 541d are supported by holders 541f and 541h, respectively. The holders 541f and 541h include protrusions 541n and 541o, respectively, and are movable parallel to the L direction by linear stages 541i and 541j, respectively.

The linear stage 541i includes a plunger 541k and a micrometer 541p. The protrusion 541n of the holder 541f is sandwiched between the plunger 541k and the micrometer 541p. The plunger 541k includes an unillustrated spring. The micrometer 541p is configured such that a distal end in contact with the protrusion 541n expands and contracts parallel to the L direction in response to a control signal from the laser processing processor 53 or the laser control processor 13. In response to expansion and contraction of the distal end of the micrometer 541p, the protrusion 541n of the holder 541f is pressed by the plunger 541k or the micrometer 541p, and the holder 541f moves in a direction of an arrow A1 together with the convex lens 541b.

The linear stage 541j includes a plunger 541m and a micrometer 541q. The configuration for the linear stage 541j to move the convex lens 541d in a direction of an arrow A2 is the same as that of the linear stage 541i.

The concave lens 541a and the convex lens 541b have respective focal axes that are parallel to the H direction. When the focal axes coincide with each other, the concave lens 541a and the convex lens 541b transmit the pulse laser beam Out without changing a beam divergence angle in the V direction as illustrated by broken lines in FIG. 16. When the convex lens 541b is moved in the direction of the arrow A1, it is possible to adjust the beam divergence angle in the V direction in a positive direction as illustrated by chain lines in FIG. 16, or adjust the beam divergence angle in the V direction in a negative direction as illustrated by two-dot chain lines.

The concave lens 541c and the convex lens 541d have respective focal axes that are parallel to the V direction. When the focal axes coincide with each other, the concave lens 541c and the convex lens 541d transmit the pulse laser beam Out without changing a beam divergence angle in the H direction as illustrated by broken lines in FIG. 15. When the convex lens 541d is moved in the direction of the arrow A2, it is possible to adjust the beam divergence angle in the H direction in a positive direction as illustrated by chain lines in FIG. 15, or to adjust the beam divergence angle in the H direction in a negative direction as illustrated by two-dot chain lines.

### 5.1.2 Effect

(13) According to the first example, the divergence adjuster 541 is configured to adjust the beam divergence angles in the V direction and the H direction. Thus, the beam divergences BDV and BDH in the V direction and the H direction can be controlled independently of each other.

FIG. 17 illustrates a principle that the beam divergences BDV and BDH are adjusted in the first example.

FIG. 17 illustrates a state in which the pulse laser beam Out having passed through the divergence adjuster 541 is condensed through the convex lens 57 included in the measuring instrument 55. As illustrated by broken lines in FIG. 17, when the pulse laser beam Out having passed through the divergence adjuster 541 is parallel light, a position F at the focal length f₅₇ from the convex lens 57 is the beam waist position where the beam is the narrowest. On the other hand, as illustrated by the chain lines in FIG. 17, when the pulse laser beam Out having passed through the divergence adjuster 541 has a positive divergence angle, a position W farther than the focal length f₅₇ from the convex lens 57 is the beam waist position where the beam is the narrowest. By changing the divergence angle of the pulse laser beam Out in this way, the beam waist position is shifted, so that a beam width at the position F of the focal point can be changed, and the beam divergences BDV and BDH can be adjusted.

When adjusting the beam divergences BDV and BDH in the first example, a minimum value of the beam divergences BDV and BDH depends on a beam width D_{w} at the beam waist position W. The beam width D_{w} at the beam waist position W is given by Equation 2 below.

$${D}_{W} = ( 4 / π ) λ {M}^{2} / NA = \{ ( 8 / π ) ( {F}_{W} / {D}_{L} ) \} \cdot λ {M}^{2} … \qquad Equation 2$$

Here, λ is a wavelength of the pulse laser beam Out, M² is an M-square value of the pulse laser beam Out, and NA is a numerical aperture of the convex lens 57.

Further, F_{w} is a distance from the convex lens 57 to the beam waist position W, and D_{L} is a beam diameter given by a total width of the beam cross section of the pulse laser beam Out entering the convex lens 57. The numerical aperture NA is given by (½)D_{L}/F_{w}.

As can be seen from Equation 2, the beam width D_{w}, which is the total width of the beam cross section at the beam waist position W, is proportional to the M-square value of the pulse laser beam Out and is also proportional to F_{w}/D_{L}.

In order to widen an adjustment range of the beam divergences BDV and BDH in the first example, it is effective to reduce the beam width D_{w} at the beam waist position W by reducing the M-square value of the pulse laser beam Out, for example. By adjusting the divergence angle of the pulse laser beam Out and bringing the beam waist position W closer to the position F of the focal point, the beam divergences BDV and BDH can be minimized.

### 5.2 Divergence Adjuster 542 that Adjusts Beam Width

### 5.2.1 Configuration and Operation

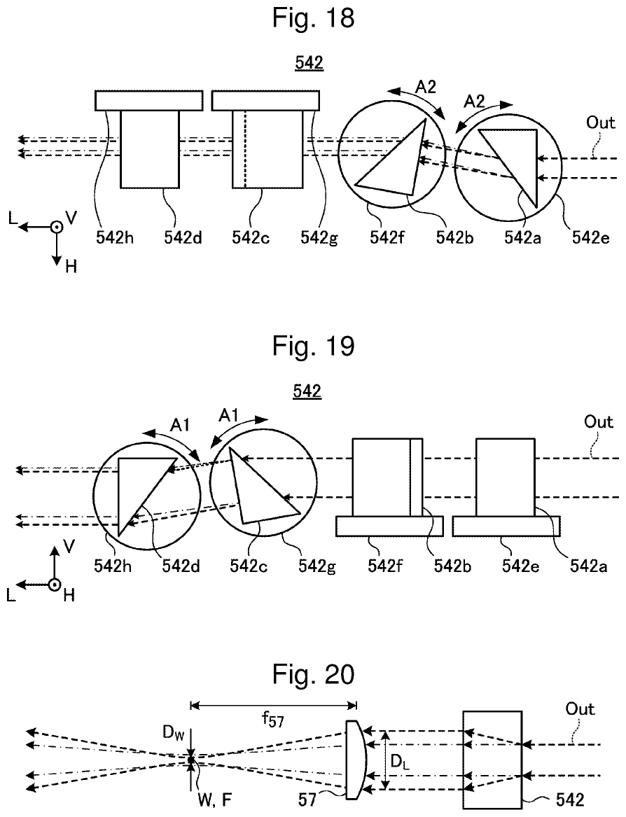

FIG. 18 and FIG. 19 schematically illustrate a second example of a divergence adjuster. FIG. 18 is a view of a divergence adjuster 542 in the −V direction, and FIG. 19 is a view in the −H direction.

In the second example, the divergence adjuster 542 includes two beam expanders. For example, one of the two beam expanders is configured by a set of similar prisms 542a and 542b, and the other is configured by a set of similar prisms 542c and 542d.

Each of the prisms 542a and 542b configuring one of the beam expanders is disposed such that the pulse laser beam Out enters from one side face parallel to the V direction and the pulse laser beam Out exits from the other side face parallel to the V direction, and the prisms 542a and 542b are configured to be rotatable about an axis parallel to the V direction by rotating stages 542e and 542f, respectively. As illustrated in FIG. 18, the beam width in the H direction of the pulse laser beam Out passing through the beam expander can be adjusted by rotating the prisms 542a and 542b in directions opposite to each other so that incident angles of the pulse laser beam Out with respect to the prisms 542a and 542b are equal.

Each of the prisms 542c and 542d configuring the other beam expander is disposed such that the pulse laser beam Out enters from one side face parallel to the H direction and the pulse laser beam Out exits from the other side face parallel to the H direction, and the prisms 542c and 542d are configured to be rotatable about an axis parallel to the H direction by rotating stages 542g and 542h, respectively. As illustrated in FIG. 19, the beam width in the V direction of the pulse laser beam Out passing through the beam expander can be adjusted by rotating the prisms 542c and 542d in directions opposite to each other so that incident angles of the pulse laser beam Out with respect to the prisms 542c and 542d are equal.

Each of the two beam expanders is not limited to a case of being configured by the two prisms, and may be configured by zoom lenses. The zoom lens may be configured by a combination of three or more cylindrical lenses. One zoom lens may adjust the beam width in the V direction, and the other zoom lens may adjust the beam width in the H direction.

### 5.2.2 Effect

(14) According to the second example, the divergence adjuster 542 is configured to adjust the beam widths in the V direction and the H direction. Also in this example, the beam divergences BDV and BDH in the V direction and the H direction can be controlled independently of each other.

FIG. 20 illustrates a principle that the beam divergences BDV and BDH are adjusted in the second example. FIG. 20 illustrates a state in which the pulse laser beam Out having passed through the divergence adjuster 542 is condensed through the convex lens 57 included in the measuring instrument 55. As illustrated in FIG. 20, when the divergence adjuster 542 changes the beam width without changing the divergence angle of the pulse laser beam Out, the beam waist position does not change and the M-square value does not change either, however, since the beam diameter D_{L} of the pulse laser beam Out entering the convex lens 57 changes, F_{w}/D_{L} indicated in Equation 2 changes. Accordingly, the beam width D_{w} at the beam waist position W is changed and the beam divergences BDV and BDH can be adjusted. While FIG. 20 illustrates a case where the beam waist position W coincides with the position F of the focal point of the convex lens 57, the beam width at the position F can be changed by changing the beam diameter D_{L} of the pulse laser beam Out entering the convex lens 57 even at a position other than the beam waist position W.

### 5.3 Divergence Adjuster 543 that Tentatively Condenses Light and Also Performs Fine Adjustment by Slit

### 5.3.1 Configuration and Operation

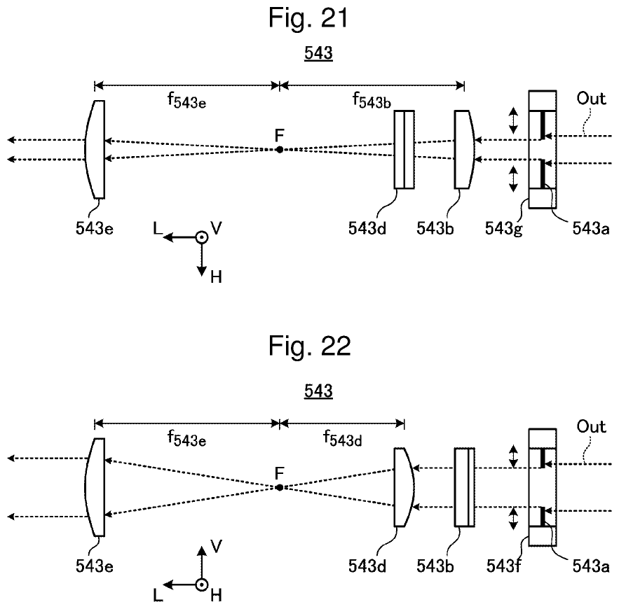

FIG. 21 and FIG. 22 schematically illustrate a third example of a divergence adjuster. FIG. 21 is a view of a divergence adjuster 543 in the −V direction, and FIG. 22 is a view in the −H direction.

In the third example, the divergence adjuster 543 includes a variable slit 543a, first and second cylindrical convex lenses 543d and 543b, and a collimator lens 543e. Positional relationships of these optical elements may be fixed to each other.

An opening width of the variable slit 543a in the V direction is adjusted by an actuator 543f, and an opening width in the H direction is adjusted by an actuator 543g. The variable slit 543a can adjust respective beam widths in the V direction and the H direction by allowing passage of a portion corresponding to the respective opening widths in the V direction and the H direction of the pulse laser beam Out having entered the divergence adjuster 543 and blocking a portion exceeding the opening widths. The variable slit 543a may be able to adjust the beam width in either the V direction or the H direction.

The first and second cylindrical convex lenses 543d and 543b are disposed on an optical path of the pulse laser beam Out having passed through the variable slit 543a. A rear focal axis of the first cylindrical convex lens 543d is parallel to the H direction and is located at a position F of a front focal point of the collimator lens 543e. A rear focal axis of the second cylindrical convex lens 543b is parallel to the V direction and is located at the position F of the front focal point of the collimator lens 543e. Thus, the first and second cylindrical convex lenses 543d and 543b condense the pulse laser beam Out in the V direction and the H direction, respectively.

In an excimer laser apparatus, since the M-square value in the V direction is larger than the M-square value in the H direction, the beam diameter in the V direction and the beam diameter in the H direction at the position F can be made closer to each other by making a focal length f_{543d} of the first cylindrical convex lens 543d shorter than a focal length f_{543b} of the second cylindrical convex lens 543b.

The collimator lens 543e is located on an optical path of the pulse laser beam Out having passed through the first and second cylindrical convex lenses 543d and 543b. The collimator lens 543e has a focal length f₅₄₃ₑ. The collimator lens 543e may be configured by a spherical convex lens, or may be configured by a double-sided cylindrical convex lens having a focal axis in the V direction and a focal axis in the H direction. Further, the collimator lens 543e is not limited to a single lens, and may include a plurality of lenses. Thus, the collimator lens 543e collimates the pulse laser beam Out condensed by the first and second cylindrical convex lenses 543d and 543b.

### 5.3.2 Effect

(15) According to the third example, the divergence adjuster 543 includes the first and second cylindrical convex lenses 543d and 543b that condense the pulse laser beam Out in the V direction and the H direction, respectively, and the collimator lens 543e that collimates the pulse laser beam Out condensed by the first and second cylindrical convex lenses 543d and 543b. Accordingly, the beam cross section on the workpiece SUB is a transfer image of the beam cross section at the position F of the front focal point of the collimator lens 543e. Therefore, by bringing the beam cross section at the position F closer to a true circle by using the first and second cylindrical convex lenses 543d and 543b, the beam cross section on the workpiece SUB can be made closer to a true circle.

When the M-square values in the V direction and the H direction of the pulse laser beam Out entering the divergence adjuster 543 are known in advance, it is desirable to determine the focal lengths f_{543d} and f_{543b} of the first and second cylindrical convex lenses 543d and 543b so that the beam diameter in the V direction and the beam diameter in the H direction at the position F of the focal point are the same. Specifically, they are calculated as follows.

In the configuration illustrated in FIG. 21 and FIG. 22, it is assumed that the beam waist position W coincides with the position F of the focal point. In Equation 2, when the beam width D_{w} at the beam waist position W is replaced with the target spot diameter Dt and the distance F_{w} to the beam waist position W is replaced with a focal length ft of the cylindrical convex lens, the focal length ft of the cylindrical convex lens is obtained by a following equation.

$$ft = π \cdot Dt \cdot {D}_{L} / ( λ {M}^{2} )$$

More specifically, when a beam diameter in the V direction of the pulse laser beam Out entering the divergence adjuster 543 is D_{LV} and an M-square value in the V direction is M²ᵥ, a focal length ftᵥ of the first cylindrical convex lens 543d is obtained by Equation 3 below.

$${ft}_{v} = π \cdot Dt \cdot {D}_{L V} / ( λ {{M}^{2}}_{v} ) … \qquad Equation 3$$

When a beam diameter in the H direction of the pulse laser beam Out entering the divergence adjuster 543 is D_{LH} and an M-square value in the H direction is M²_{H}, a focal length ft_{H} of the second cylindrical convex lens 543b is obtained by Equation 4 below.

$${ft}_{H} = π \cdot Dt \cdot {D}_{L H} / ( λ {{M}^{2}}_{H} ) \qquad Equation 4$$

(16) According to the third example, the divergence adjuster 543 includes the variable slit 543a that adjusts the beam width in either the V direction or the H direction by blocking a portion of the pulse laser beam Out entering the first and second cylindrical convex lenses 543d and 543b. Thus, the shape of the beam cross section on the workpiece SUB can be finely adjusted.

### 5.4 Divergence Adjuster 544 that Tentatively Condenses Light and Also Performs Fine Adjustment by Lens Position

### 5.4.1 Configuration and Operation

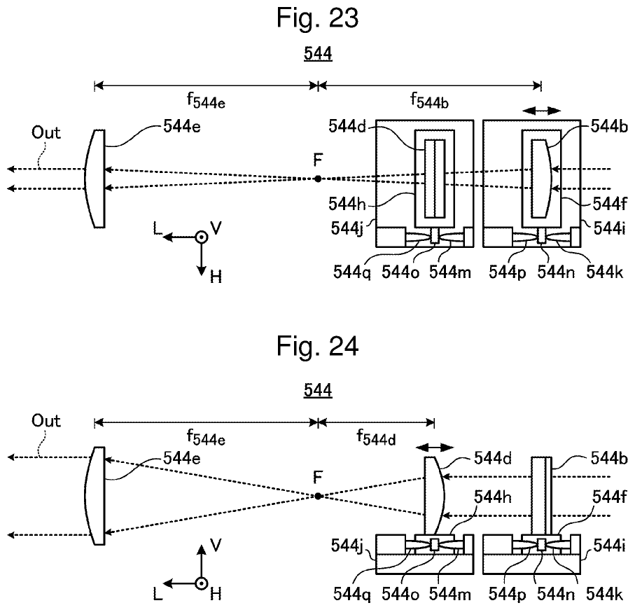

FIG. 23 and FIG. 24 schematically illustrate a fourth example of a divergence adjuster. FIG. 23 is a view of a divergence adjuster 544 in the −V direction, and FIG. 24 is a view in the −H direction.

The fourth example differs from the third example in that the divergence adjuster 544 does not include the variable slit 543a and that first and second cylindrical convex lenses 544d and 544b are movable parallel to the L direction by linear stages 544j and 544i, respectively. In other respects, the description of the first and second cylindrical convex lenses 543d and 543b and the collimator lens 543e in the third example also applies to the description of the first and second cylindrical convex lenses 544d and 544b and a collimator lens 544e in the fourth example.

The configuration of moving the first and second cylindrical convex lenses 544d and 544b by the linear stages 544j and 544i is the same as the configuration of moving the cylindrical convex lenses 541d and 541b in the first example. The linear stages 544j and 544i correspond to first and second linear stages in the present disclosure, respectively.

### 5.4.2 Effect

(17) According to the fourth example, the divergence adjuster 544 includes the linear stages 544j and 544i that move the first and second cylindrical convex lenses 544d and 544b, respectively, along the traveling direction of the pulse laser beam Out. Thus, by changing the beam waist position inside the divergence adjuster 544 and changing the beam cross section at the position F of the focal point, the shape of the beam cross section on the workpiece SUB can be finely adjusted. In the fourth example, the variable slit 543a similar to that in the third example may be further provided to apply fine adjustment by the variable slit 543a.

### 5.5 Divergence Adjuster 545 Including Optical Pulse Stretcher Misaligned in H Direction

### 5.5.1 Configuration and Operation

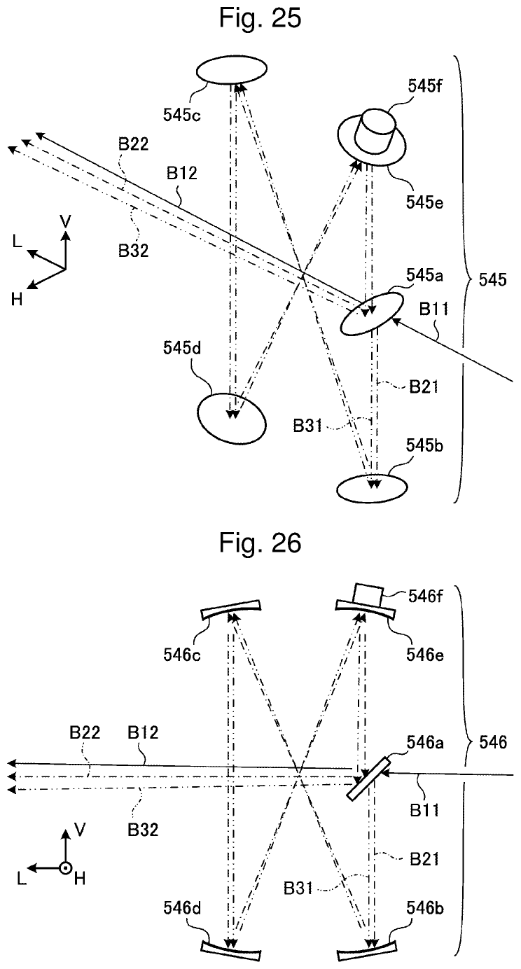

FIG. 25 schematically illustrates a fifth example of a divergence adjuster. In the fifth example, a divergence adjuster 545 is configured by an optical pulse stretcher that branches the optical path of the pulse laser beam Out. The optical pulse stretcher includes a beam splitter 545a, concave mirrors 545b to 545e, and an actuator 545f.

The beam splitter 545a is disposed on an optical path of the pulse laser beam Out that enters the divergence adjuster 545 as a beam B11. A reflectance of the beam splitter 545a is, for example, 60%.

The concave mirrors 545b, 545c, 545d and 545e are spherical mirrors and are disposed in this order on an optical path of a beam B21 reflected by the beam splitter 545a. The concave mirrors 545b to 545e configure a loop-shaped delay optical path.

The actuator 545f is configured to be able to change a posture of the concave mirror 545e.

The beam splitter 545a transmits a portion of the beam B11 as a beam B12 and reflects the other portion as the beam B21. The concave mirrors 545b to 545e sequentially reflect the beam B21 to make it enter the beam splitter 545a.

The beam splitter 545a reflects a portion of the beam B21 as a beam B22 and transmits the other portion as a beam B31. The concave mirrors 545b to 545e sequentially reflect the beam B31 to make it enter the beam splitter 545a.

The beam splitter 545a reflects a portion of the beam B31 as a beam B32.

In this way, the beams B12, B22, and B32 are output from the divergence adjuster 545. At this time, the concave mirrors 545b to 545e are intentionally misaligned so that the beams B12, B22, and B32 are branched as beams shifted from each other in the H direction.

The actuator 545f finely adjusts a deviation amount in the H direction of the beams B12, B22, and B32 by changing the posture of the concave mirror 545e.

In this way, the divergence adjuster 545 adjusts the beam divergence BDH in the H direction of the pulse laser beam Out including the beams B12, B22, and B32.

In order to prevent the beams B12, B22, and B32 from interfering with each other, an optical path length of the delay optical path configured by the concave mirrors 545b to 545e is preferably set to be longer than a temporal coherent length of the pulse laser beam Out.

Further, it is desirable that the concave mirrors 545b to 545e are disposed so that an image of the beam B11 in the beam splitter 545a is formed as an inverted image between the concave mirrors 545c and 545d as the beam B21 and is formed again to be an erect image when entering the beam splitter 545a. Here, when focal lengths of the concave mirrors 545b to 545e are all a same f₅₄₅, the optical path length of the delay optical path is eight times f₅₄₅.

### 5.5.2 Effect

(18) According to the fifth example, the divergence adjuster 545 includes the optical pulse stretcher configured to branch the optical path of the pulse laser beam Out in the H direction. Thus, not only the beam divergence BDH can be adjusted but also a pulse time width can be extended at the same time.

### 5.6 Divergence Adjuster 546 Including Optical Pulse Stretcher Misaligned in V Direction

FIG. 26 schematically illustrates a sixth example of a divergence adjuster. In the sixth example, a beam splitter 546a, concave mirrors 546b to 546e, and an actuator 546f included in a divergence adjuster 546 have the same configuration as that of the beam splitter 545a, the concave mirrors 545b to 545e, and the actuator 545f in the fifth example.

The sixth example is different from the fifth example as follows.

The concave mirrors 546b to 546e are intentionally misaligned so that the beams B12, B22, and B32 output from the divergence adjuster 546 are branched as beams shifted from each other in the V direction.

The actuator 546f finely adjusts a deviation amount in the V direction of the beams B12, B22, and B32 by changing a posture of the concave mirror 546e.

In this way, the divergence adjuster 546 adjusts the beam divergence BDV in the V direction of the pulse laser beam Out including the beams B12, B22, and B32.

In other respects, the sixth example is similar to the fifth example.

By disposing the divergence adjuster 545 in the fifth example and the divergence adjuster 546 in the sixth example on the optical path of the pulse laser beam Out, the beam divergences BDV and BDH in both the H direction and the V direction can be adjusted.

### 6. Improved Laser Apparatus

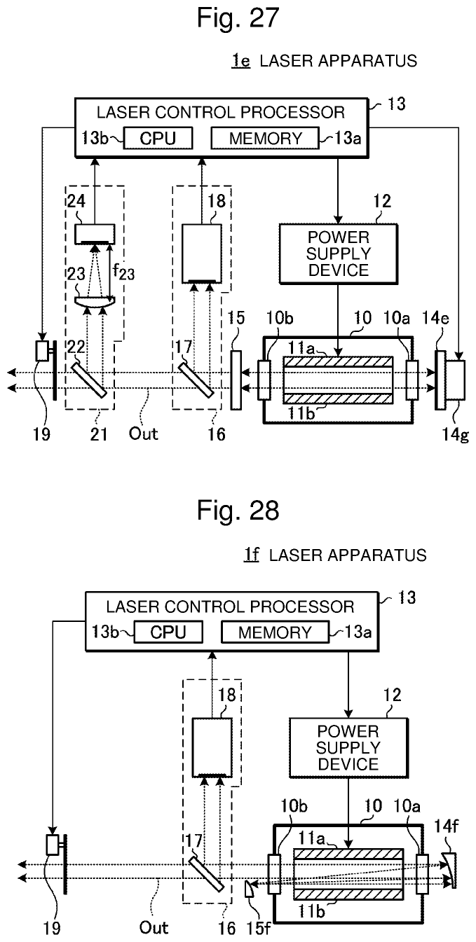

An improved laser apparatus will be described with reference to FIGS. 27 to 30. In order to widen the adjustment range of the beam divergences BDV and BDH, it is desirable to use any of improved laser apparatuses described below, instead of the laser apparatus 1.

### 6.1 Laser Apparatus 1e Capable of Posture Controlling Optical Resonator

FIG. 27 schematically illustrates a first example of an improved laser apparatus. A laser apparatus 1e illustrated in FIG. 27 includes the measuring instrument 21 in addition to the configuration of the laser apparatus 1 illustrated in FIG. 1, FIG. 4, FIG. 11, and FIG. 13. Further, the laser apparatus 1e includes, instead of the rear mirror 14, a rear mirror 14e provided with an actuator 14g. The rear mirror 14e and the output coupling mirror 15 configure an optical resonator.

A configuration of the measuring instrument 21 is the same as that described with reference to FIG. 10.

The actuator 14g is configured to be able to change a posture of the rear mirror 14e about an axis parallel to each of the V direction and the H direction.

The laser control processor 13 feedback-controls the actuator 14g so as to reduce the beam divergences BDV and BDH measured by the measuring instrument 21. Thus, even when the components of the laser apparatus 1e change in temperature, the beam divergences BDV and BDH can be suppressed from being increased by misalignment of the rear mirror 14e and the output coupling mirror 15. By using such a laser apparatus 1e, the adjustment range of the beam divergences BDV and BDH by the divergence adjuster 54 can be widened.

While a case where the rear mirror 14e is made rotatable about an axis parallel to each of the V direction and the H direction is described in FIG. 27, the output coupling mirror 15 may be made rotatable about an axis parallel to each of the V direction and the H direction instead of the rear mirror 14e.

Further, each of the rear mirror 14e and the output coupling mirror 15 may be made rotatable about an axis parallel to the V direction and the H direction. Accordingly, not only the beam divergences BDV and BDH but also the beam pointings BPV and BPH can be adjusted. The measuring instrument 21 can measure both the beam divergences BDV and BDH and the beam pointings BPV and BPH, and the laser control processor 13 may feedback-control postures of the rear mirror 14e and the output coupling mirror 15 so that the beam divergences BDV and BDH and the beam pointings BPV and BPH measured by the measuring instrument 21 become desired values.

In other respects, the laser apparatus 1e may be similar to the laser apparatus 1. Further, in the laser apparatus 1e, the divergence adjuster 20 may be provided in a same manner as in the laser apparatus 1b.

### 6.2 Laser Apparatus 1f Including Unstable Resonator

FIG. 28 schematically illustrates a second example of an improved laser apparatus. A laser apparatus 1f illustrated in FIG. 28 differs from the laser apparatus 1 illustrated in FIG. 1, FIG. 4, FIG. 11, and FIG. 13 in that the laser apparatus 1f includes a concave mirror 14f and a convex mirror 15f configuring an unstable resonator, instead of the rear mirror 14 and the output coupling mirror 15.

The concave mirror 14f and the convex mirror 15f are spherical mirrors, and are disposed so that positions of focal points coincide with each other. A magnification of these mirrors is, for example, 5 times or more and 10 times or less. The convex mirror 15f is located so as to block a part of an optical path of light output from the window 10b.

A portion of the light output from the window 10b of the laser chamber 10 is reflected by the convex mirror 15f, passes through the discharge space between the discharge electrodes 11a and 11b while gradually diverging, and enters the concave mirror 14f.

The light reflected by the concave mirror 14f passes through the discharge space between the discharge electrodes 11a and 11b as parallel light, a portion of it enters the convex mirror 15f and is reflected again toward the concave mirror 14f, and the other portion is output as the pulse laser beam Out without entering the convex mirror 15f.

According to the second example, a spatial transverse mode count of the output pulse laser beam Out is reduced, and the pulse laser beam Out close to a single transverse mode can be generated. As a result, the beam divergences BDV and BDH in the V direction and the H direction can be reduced. By using such a laser apparatus 1f, the adjustment range of the beam divergences BDV and BDH by the divergence adjuster 54 can be widened. Further, it is possible to process a smaller hole as compared with a case of using the laser apparatus 1.

The concave mirror 14f and the convex mirror 15f may be cylindrical mirrors each having a focal axis that is parallel to the H direction. The focal axes of the concave mirror 14f and the convex mirror 15f preferably coincide. In this case, the concave mirror 14f and the convex mirror 15f become an unstable resonator in the V direction and a stable resonator in the H direction. As a result, a spatial transverse mode count in the V direction is reduced to be approximately the same as a spatial transverse mode count in the H direction, and the beam divergence BDV in the V direction can be reduced. Therefore, an adjustment range of the beam divergence BDV in the V direction by the divergence adjuster 54 can be widened. Further, it is possible to process a smaller hole as compared with a case of using the laser apparatus 1. In addition, resonator loss can be reduced as compared with a case of using a spherical mirror is used, and the pulse laser beam Out having higher energy can be output.

In the second example, as in the first example, the posture of one or both of the concave mirror 14f and the convex mirror 15f may be controlled.

In other respects, the laser apparatus 1f may be similar to the laser apparatus 1. Further, in the laser apparatus 1f, the divergence adjuster 20 may be provided in the same manner as in the laser apparatus 1b.

### 6.3 Laser Apparatus 1g Including Amplifier PA

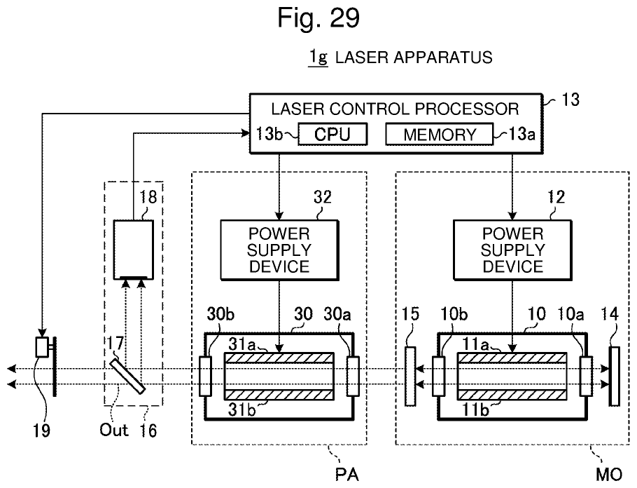

FIG. 29 schematically illustrates a third example of an improved laser apparatus. A laser apparatus 1g illustrated in FIG. 29 differs from the laser apparatus 1 illustrated in FIG. 1, FIG. 4, FIG. 11, and FIG. 13 in that the laser apparatus 1g includes an amplifier PA between the output coupling mirror 15 and the monitor module 16.

The laser chamber 10, the power supply device 12, the rear mirror 14, and the output coupling mirror 15 configure a master oscillator MO. The amplifier PA includes a laser chamber 30 and a power supply device 32. The laser chamber 30 and the power supply device 32 may be configured similarly to the laser chamber 10 and the power supply device 12. The amplifier PA may not include an optical resonator.

The amplifier PA is configured to amplify a pulse laser beam output from the master oscillator MO. A time difference between trigger signals supplied to the power supply devices 12 and 32 is set so that timing at which the pulse laser beam output from the master oscillator MO enters the amplifier PA is synchronized with timing at which discharge occurs inside the laser chamber 30 by the power supply device 32 generating a high voltage. The laser control processor 13 feedback-controls set voltages that are set in the power supply devices 12 and 32 based on the data of the pulse energy measured by the monitor module 16.

According to the third example, the pulse laser beam Out having the pulse energy sufficiently high for laser processing can be output from the laser apparatus 1g.

In the third example, an unstable resonator similar to that in the second example may be used as an optical resonator included in the master oscillator MO.

In the third example, as in the first example, the posture of one or both of the rear mirror 14 and the output coupling mirror 15 may be controlled.

In other respects, the laser apparatus 1g may be similar to the laser apparatus 1. Further, in the laser apparatus 1g, the divergence adjuster 20 may be provided in the same manner as in the laser apparatus 1b.

### 6.4 Laser Apparatus 1h Including Solid-State Laser

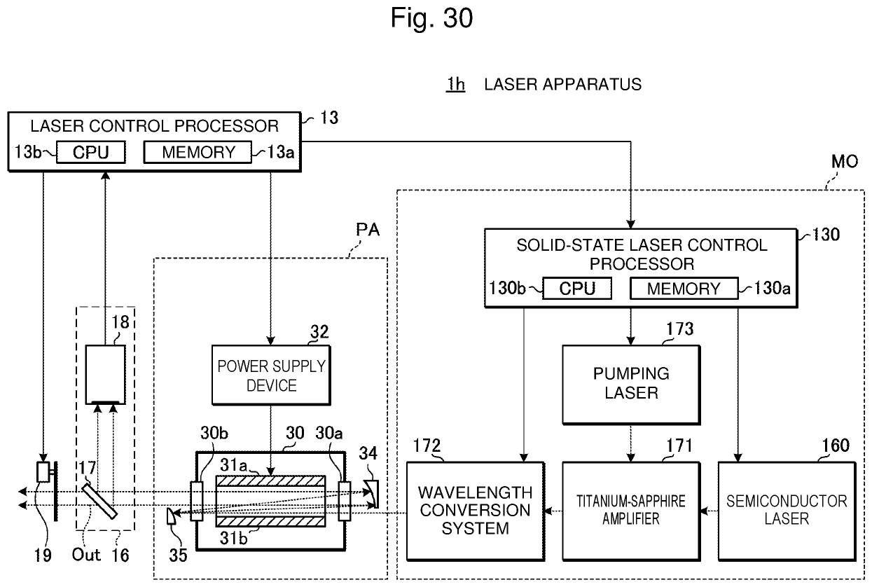

FIG. 30 schematically illustrates a fourth example of an improved laser apparatus. A laser apparatus 1h illustrated in FIG. 30 differs from the laser apparatus 1g illustrated in FIG. 29 in that the master oscillator MO includes a solid-state laser.

### 6.4.1 Configuration

The laser apparatus 1h includes the master oscillator MO, the amplifier PA, and the monitor module 16. The master oscillator MO includes a solid-state laser and the amplifier PA includes an excimer laser.

The master oscillator MO includes a semiconductor laser 160, a titanium-sapphire amplifier 171, a wavelength conversion system 172, a pumping laser 173, and a solid-state laser control processor 130.

The semiconductor laser 160 is a distributed feedback type semiconductor laser that outputs a CW laser beam having a wavelength of about 773.6 nm, and is configured to be able to change an oscillation wavelength by changing a set temperature of a semiconductor.

The titanium-sapphire amplifier 171 is an amplifier including a titanium-sapphire crystal.

The pumping laser 173 is a laser apparatus that outputs a second harmonic of a YLF (yttrium lithium fluoride) laser to excite the titanium-sapphire crystal of the titanium-sapphire amplifier 171.

The wavelength conversion system 172 includes an LBO (lithium triborate) crystal and a KBBF (Potassium beryllium fluoroborate) crystal and outputs a fourth harmonic of incident light. A wavelength of the fourth harmonic is about 193.4 nm and is substantially equal to an oscillation wavelength of an ArF excimer laser apparatus.

The solid-state laser control processor 130 is a processor including a memory 130a in which a control program is stored, and a CPU 130b that executes the control program. The solid-state laser control processor 130 is specifically configured or programmed to perform various kinds of processing included in the present disclosure.

The amplifier PA is an ArF excimer laser apparatus including the laser chamber 30, the power supply device 32, a concave mirror 34, and a convex mirror 35. Configurations of the laser chamber 30 and the power supply device 32 included in the amplifier PA are the same as the corresponding configurations in the laser apparatus 1g described with reference to FIG. 29.

The convex mirror 35 is disposed on an optical path of a pulse laser beam which has been output from the master oscillator MO and has passed through the laser chamber 30.

The concave mirror 34 is disposed on an optical path of a pulse laser beam which has been reflected by the convex mirror 35 and has passed through the laser chamber 30 again.

Configurations of the monitor module 16 and the laser control processor 13 are the same as the corresponding configurations in the laser apparatus 1 illustrated in FIG. 1, FIG. 4, FIG. 11, and FIG. 13.

### 6.4.2 Operation

In the master oscillator MO, the semiconductor laser 160 outputs a CW laser beam having a wavelength of about 773.6 nm, and the titanium-sapphire amplifier 171 pulses, amplifies, and outputs the laser beam. The wavelength conversion system 172 converts a pulse laser beam having a wavelength of about 773.6 nm to a pulse laser beam having a wavelength of about 193.4 nm, and outputs the pulse laser beam to the amplifier PA.

The pulse laser beam which has entered the amplifier PA passes through a discharge space in the laser chamber 30, is then reflected by the convex mirror 35, and is given a beam convergence angle corresponding to a curvature of the convex mirror 35. This pulse laser beam passes through the discharge space in the laser chamber 30 again.

The pulse laser beam which has been reflected by the convex mirror 35 and has passed through the laser chamber 30 is reflected by the concave mirror 34 and is returned to substantially parallel light. The pulse laser beam passes through the discharge space in the laser chamber 30 once more, and is output to outside of the laser apparatus 1h as the pulse laser beam Out through the monitor module 16.

A high voltage is applied to the electrodes 30a and 30b so that discharge starts in the discharge space in the laser chamber 30 when the pulse laser beam enters the laser chamber 30 from the master oscillator MO. The pulse laser beam is expanded in beam width by the convex mirror 35 and the concave mirror 34, is amplified while passing through the discharge space three times, and is output to the outside of the laser apparatus 1h.

According to the fourth example, since the pulse laser beam of a single transverse mode that is output from the master oscillator MO including the solid-state laser is amplified and output, the beam divergences BDV and BDH in the V direction and the H direction can be reduced. By using such a laser apparatus 1h, the adjustment range of the beam divergences BDV and BDH by the divergence adjuster 54 can be widened. Further, it is possible to process a smaller hole as compared with a case of using the laser apparatus 1.

While the fourth example describes a case of configuring an optical resonator included in the amplifier PA by the concave mirror 34 and the convex mirror 35, the optical resonator may be a Fabry-Perot resonator or a ring resonator.

While the fourth example describes a combination of the master oscillator MO that outputs a pulse laser beam having a wavelength of about 193.4 nm and the ArF excimer laser apparatus that amplifies a wavelength component of about 193.4 nm, a combination of the master oscillator MO that outputs a pulse laser beam having a wavelength of about 248.4 nm and the KrF excimer laser apparatus that amplifies a wavelength component of about 248.4 nm may be used.

In other respects, the laser apparatus 1h may be similar to the laser apparatus 1. Further, in the laser apparatus 1h, the divergence adjuster 20 may be provided in the same manner as in the laser apparatus 1b.

7. Others FIG. 31 schematically illustrates a configuration of an electronic device. The electronic device illustrated in FIG. 31 includes the integrated circuit chip IC, the interposer IP, and the circuit board CS.

The integrated circuit chip IC is, for example, a chip in which an unillustrated integrated circuit is formed on a silicon substrate. The integrated circuit chip IC is provided with a plurality of bumps ICB electrically connected to the integrated circuit.

The interposer IP includes an insulating substrate in which a plurality of unillustrated through-holes are formed, and an unillustrated conductor that electrically connects front and back surfaces of the substrate is provided in each of the through-holes. A plurality of unillustrated lands connected to the bumps ICB are formed on one surface of the interposer IP, and each of the lands is electrically connected to any one of the conductors in the through-holes. A plurality of bumps IPB are provided on the other surface of the interposer IP, and each of the bumps IPB is electrically connected to any one of the conductors in the through-holes.

A plurality of unillustrated lands connected to the bumps IPB are formed on one surface of the circuit board CS. The circuit board CS includes a plurality of terminals electrically connected to the lands.

FIG. 32 is a flowchart illustrating an electronic device manufacturing method.

In S1, laser processing and wiring formation of the interposer substrate configuring the interposer IP are performed. The laser processing of the interposer substrate includes forming through-holes by irradiating the interposer substrate with the pulse laser beam Out. The wiring formation includes forming a conductive film on an inner wall surface of the through-hole formed in the interposer substrate. Through such a process, the interposer IP is manufactured.

In S2, the interposer IP and the integrated circuit chip IC are coupled. This process includes, for example, disposing the bumps ICB of the integrated circuit chip IC on the lands of the interposer IP and electrically connecting the bumps ICB and the lands.

In S3, the interposer IP and the circuit board CS are coupled. This process includes, for example, disposing the bumps IPB of the interposer IP on the lands of the circuit board CS and electrically connecting the bumps IPB and the lands.

The description above is intended to be illustrative and the present disclosure is not limited thereto. Therefore, it is obvious to those skilled in the art that modifications to the embodiments of the present disclosure would be possible without departing from the scope of the claims. Further, it is also obvious for those skilled in the art that the embodiments of the present disclosure would be appropriately combined.

The terms used throughout the present specification and the claims should be interpreted as non-limiting terms unless clearly described. For example, terms such as “comprise”, “include”, “have”, and “contain” should not be interpreted to be exclusive of other structural elements. Further, indefinite articles “a/an” should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser processing system comprising:
a laser apparatus configured to output a pulse laser beam;
a divergence adjuster configured to adjust a first beam divergence in a first direction of the pulse laser beam and a second beam divergence in a second direction which intersects the first direction;
a measuring instrument configured to measure the first and second beam divergences of the pulse laser beam having passed through the divergence adjuster;
a diffractive optical element configured to branch the pulse laser beam having passed through the measuring instrument; and
a processor configured to control the divergence adjuster such that the first and second beam divergences approach respective target values based on measurement results of the first and second beam divergences by the measuring instrument.

2. The laser processing system according to claim 1, wherein
a difference between the target values of the first and second beam divergences is smaller than a difference between a third beam divergence in the first direction and a fourth beam divergence in the second direction of the pulse laser beam entering the divergence adjuster.

3. The laser processing system according to claim 1, further comprising
a beam steering device disposed on an optical path of the pulse laser beam between the laser apparatus and the diffractive optical element and configured to adjust a traveling direction of the pulse laser beam, wherein
the measuring instrument further measures a beam pointing of the pulse laser beam having passed through the beam steering device, and
the processor controls the beam steering device so that the beam pointing approaches a target value thereof based on a measurement result of the beam pointing by the measuring instrument.

4. The laser processing system according to claim 1, further comprising
a shutter disposed on an optical path of the pulse laser beam having passed through the measuring instrument and configured to be able to switch passing and blocking of the pulse laser beam, wherein
the processor controls the shutter so that the pulse laser beam is blocked until measurement results of the first and second beam divergences by the measuring instrument fall within respective allowable ranges including the respective target values.

5. The laser processing system according to claim 1, further comprising
a light condensing optical system disposed on an optical path of the pulse laser beam having passed through the diffractive optical element, wherein
a workpiece is disposed on a focal plane of the light condensing optical system.

6. The laser processing system according to claim 1, wherein
the laser apparatus includes an optical resonator housed in a first housing, and
the divergence adjuster and the diffractive optical element are housed in a second housing.

7. The laser processing system according to claim 1, wherein
the laser apparatus includes an optical resonator and the divergence adjuster housed in a first housing, and
the diffractive optical element is housed in a second housing.

8. The laser processing system according to claim 1, further comprising:
a light condensing optical system disposed on an optical path of the pulse laser beam having passed through the diffractive optical element;
a mask disposed on a focal plane of the light condensing optical system and provided with a plurality of openings; and
a projection optical system disposed on an optical path of the pulse laser beam having passed through the mask.

9. The laser processing system according to claim 8, wherein
the light condensing optical system condenses each of a plurality of branched light beams of the pulse laser beam branched by the diffractive optical element so that cross sections of the branched light beams overlap the respective openings.

10. The laser processing system according to claim 1, further comprising:
a light condensing lens disposed on an optical path of the pulse laser beam having passed through the measuring instrument and configured to condense the pulse laser beam;
a mask disposed on an optical path of the pulse laser beam having passed through the light condensing lens; and
a collimator optical system disposed on an optical path of the pulse laser beam between the mask and the diffractive optical element.

11. The laser processing system according to claim 10, wherein
the mask is located at a focal point of the light condensing lens.

12. The laser processing system according to claim 10, further comprising
a light condensing optical system disposed on an optical path of the pulse laser beam having passed through the diffractive optical element, wherein
the collimator optical system, the diffractive optical element, and the light condensing optical system project an image of the mask to a plurality of positions of a workpiece.

13. The laser processing according to claim 1, wherein
the divergence adjuster is configured to adjust beam divergence angles in the first and second directions.

14. The laser processing system according to claim 1, wherein
the divergence adjuster is configured to adjust beam widths in the first and second directions.

15. The laser processing system according to claim 1, wherein
the divergence adjuster includes first and second cylindrical convex lenses configured to condense the pulse laser beam in the first and second directions, respectively, and
a collimator lens configured to collimate the pulse laser beam condensed by the first and second cylindrical convex lenses.

16. The laser processing system according to claim 15, wherein
the divergence adjuster further includes a variable slit configured to adjust a beam width in one of the first and second directions by blocking a portion of the pulse laser beam entering the first and second cylindrical convex lenses.

17. The laser processing system according to claim 15, wherein
the divergence adjuster further includes first and second linear stages configured to move the first and second cylindrical convex lenses, respectively, along a traveling direction of the pulse laser beam.

18. The laser processing system according to claim 1, wherein
the divergence adjuster includes an optical pulse stretcher configured to branch an optical path of the pulse laser beam in one of the first and second directions.

19. A laser processing method comprising:
making a pulse laser beam be output from a laser apparatus;
making the pulse laser beam enter a divergence adjuster configured to adjust a first beam divergence in a first direction of the pulse laser beam and a second beam divergence in a second direction which intersects the first direction;
measuring the first and second beam divergences of the pulse laser beam having passed through the divergence adjuster by a measuring instrument;
controlling the divergence adjuster such that the first and second beam divergences approach respective target values based on measurement results of the first and second beam divergences by the measuring instrument; and
branching the pulse laser beam having passed through the measuring instrument by a diffractive optical element so as to irradiate a workpiece.

20. An electronic device manufacturing method comprising:
manufacturing an interposer by laser-processing an interposer substrate with a laser processing system, the laser processing system including
a laser apparatus configured to output a pulse laser beam,
a divergence adjuster configured to adjust a first beam divergence in a first direction of the pulse laser beam and a second beam divergence in a second direction which intersects the first direction,
a measuring instrument configured to measure the first and second beam divergences of the pulse laser beam having passed through the divergence adjuster,
a diffractive optical element configured to branch the pulse laser beam having passed through the measuring instrument, and
a processor configured to control the divergence adjuster such that the first and second beam divergences approach respective target values based on measurement results of the first and second beam divergences by the measuring instrument;
coupling and electrically connecting the interposer and an integrated circuit chip to each other; and
coupling and electrically connecting the interposer and a circuit board to each other.
